(19) United States
(12) Patent Application Publication
(10) Pub. No.: US 2025/0027976 A1
(43) Pub. Date: Jan. 23, 2025

(54) ELECTRIC POWER CONSUMPTION ESTIMATION APPARATUS, NON-TRANSITORY COMPUTER-READABLE STORAGE MEDIUM, AND ELECTRIC POWER CONSUMPTION ESTIMATION METHOD

(71) Applicant: Mitsubishi Electric Corporation, Tokyo (JP)

(72) Inventors: Atsuyoshi Yano, Tokyo (JP); Masahiro ABUKAWA, Tokyo (JP)

(73) Assignee: Mitsubishi Electric Corporation, Tokyo (JP)

(21) Appl. No.: 18/910,591

(22) Filed: Oct. 9, 2024

Related U.S. Application Data
(63) Continuation of application No. PCT/JP2023/018263, filed on May 16, 2023.

(30) Foreign Application Priority Data
May 25, 2022 (WO) PCT/JP2022/021342

(51) Int. Cl. G01R 19/25

(52) U.S. Cl. CPC G01R 19/2513

(57) ABSTRACT

An electric power consumption estimation apparatus includes: a total electric power consumption data acquisition unit that acquires total electric power consumption data indicative of a total electric power consumption from an electric power meter; an operating state data acquisition unit that acquires operating state data indicative of whether or not each of the plurality of devices is in an operating state, from each of the devices; an average electric power consumption analysis unit that estimates an average electric power consumption of each of the plurality of devices from the total electric power consumption and whether or not each of the devices is in the operating state; and an electric power consumption calculation unit that calculates a device electric power consumption, which is the electric power consumption of each of the plurality of devices for each predetermined period by using the average electric power consumption.

### CROSS REFERENCE TO RELATED APPLICATION

This application is a Continuation of PCT International Application No. PCT/JP2023/018263, filed on May 16, 2023, which claims priority under 35 U.S.C. 119 (a) to Patent Application No. PCT/JP2022/021342, filed in Japan on May 25, 2022, all of which are hereby expressly incorporated by reference into the present application.

### BACKGROUND OF THE INVENTION

### 1. Field of the Invention

The present disclosure relates to an electric power consumption estimation apparatus, a non-transitory computer-readable storage medium, and an electric power consumption estimation method.

### 2. Description of the Related Art

Non-Intrusive Load Monitoring (NILM) technology is conventionally known for determining electric power consumption of individual home appliances and the like based on information about the current measured at distribution boards in homes and the like. In recent years, a method of identifying a home appliance being used by using an identification model based on the measured current or the like has been employed. However, it is difficult for this method to identify home appliances for which an identification model has not been trained in advance.

Meanwhile, there is another method of identifying electric power consumption of individual home appliances by using a Hidden Marlov Model (HMM), which is a model generated from data. However, in the case of HMM, as the number of home appliances increases, the number of states in the HMM becomes significant, which makes its implementation difficult. Therefore, Patent Reference 1 discloses a method of implementing a model with an implementable number of states by correlating each factor with a home appliance through use of Factorial HMM (FHMM).
PATENT REFERENCE 1: Japanese Patent Application Publication No. 2013-210755

### SUMMARY OF THE INVENTION

However, while the conventional technologies are effective in identifying devices with different intrinsic waveforms, such as home appliances, it is difficult to identify the electric power consumption of each device when there are multiple devices with similar intrinsic waveforms, such as in factories where many devices of the same type or model exist, for example.

Therefore, it is an object of one or more aspects of the present disclosure to enable the estimation of electric power consumption of an individual device even when there are multiple devices with similar intrinsic waveforms.

An electric power consumption estimation apparatus according to one aspect of the present disclosure includes: processing circuitry to acquire total electric power consumption data indicative of a total electric power consumption from an electric power meter, the electric power meter being configured to measure a sum of electric power consumptions of a plurality of devices as the total electric power consumption for each predetermined period; to acquire operating state data indicative of whether or not each of the plurality of devices is in an operating state, from each of the devices; to estimate an average electric power consumption of each of the plurality of devices from the total electric power consumption and whether or not each of the devices is in the operating state; and to calculate a device electric power consumption by using the average electric power consumption, the device electric power consumption being an electric power consumption of each of the plurality of devices for each period. The processing circuitry calculates an electric power consumption matrix by using an equation, the equation stating that a product of the electric power consumption matrix and a coefficient matrix results in an observation matrix, the electric power consumption matrix having the average electric power consumption of each of the plurality of devices as a component thereof, the coefficient matrix having, as components thereof, values indicative of the plurality of devices and of whether or not the devices are in the operating state corresponding to the period, the observation matrix having the total electric power consumption corresponding to the period as components thereof.

According to one or more aspects of the present disclosure, the electric power consumption of an individual device can be estimated even when multiple devices have similar intrinsic waveforms.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a block diagram schematically illustrating a configuration of an electric power consumption estimation system including an electric power consumption estimation apparatus according to each of first to sixth embodiments;

FIG. 2 is a block diagram schematically illustrating a configuration of an average electric power consumption analysis unit in the first to third embodiments;

FIG. 3 is a schematic diagram illustrating an example of a coefficient matrix in the first embodiment;

FIG. 4 is a schematic diagram illustrating an example of an observation matrix in the first embodiment;

FIG. 5 is a schematic diagram for explaining a calculation method of an electric power consumption matrix in the first embodiment;

FIGS. 6A and 6B are block diagrams illustrating examples of hardware configurations;

FIG. 7 is a schematic diagram illustrating an example of a coefficient matrix in the second embodiment;

FIG. 8 is a schematic diagram illustrating an example of an observation matrix in the second embodiment;

FIG. 9 is a schematic diagram illustrating an example of an observation matrix in the third embodiment;

FIG. 10 is a schematic diagram for explaining a calculation method of an electric power consumption matrix in the third embodiment;

FIG. 11 is a schematic diagram illustrating an example of the electric power consumption matrix in the third embodiment;

FIG. 12 is a block diagram schematically illustrating a configuration of an average electric power consumption analysis unit in the fourth embodiment;

FIG. 13 is a schematic diagram illustrating an example of elapsed time threshold value data;

FIGS. 14A to 14C are schematic diagrams for explaining processing in which a coefficient matrix generating unit generates another mode by comparing an elapsed time and a threshold value, regarding whether a device is in an operating state or not;

FIG. 15 is a schematic diagram illustrating an example of a coefficient matrix U in the fourth embodiment;

FIG. 16 is a block diagram schematically illustrating a configuration of an average electric power consumption analysis unit in the fifth embodiment;

FIG. 17 is a schematic diagram illustrating an example of an additional electric power consumption matrix;

FIG. 18 is a block diagram schematically illustrating a configuration of an average electric power consumption analysis unit in the sixth embodiment;

FIG. 19 is a block diagram schematically illustrating a configuration of an electric power consumption estimation system including an electric power consumption estimation apparatus according to a seventh embodiment;

FIG. 20 is a block diagram schematically illustrating a configuration of an average electric power consumption analysis unit in the seventh embodiment;

FIGS. 21A and 21B are schematic diagrams illustrating an example of inverting the operating state of an electric power generating device;

FIGS. 22A and 22B are schematic diagrams illustrating an example of adding an offset value to a total electric power consumption;

FIGS. 23A and 23B are schematic diagrams illustrating an example of subtracting an offset value from a device electric power consumption of the power generating device;

FIG. 24 is a block diagram schematically illustrating a configuration of an electric power consumption estimation system including an electric power consumption estimation apparatus according to an eighth embodiment;

FIG. 25 is a block diagram schematically illustrating a configuration of an average electric power consumption analysis unit in the eighth embodiment;

FIGS. 26A and 26B are schematic diagrams illustrating an example of adding an offset value to an electric power consumption of a motor;

FIG. 27 is a block diagram schematically illustrating a configuration of a coefficient matrix generating unit in the eighth embodiment;

FIGS. 28A to 28E are schematic diagrams for explaining processing of classifying the operation state based on a rotation speed;

FIG. 29 is a schematic diagram for explaining virtual modes;

FIG. 30 is a schematic diagram illustrating a configuration of an operation mode conversion table; and

FIGS. 31A to 31H are schematic diagrams illustrating an example of converting the operation state to the virtual mode.

### DETAILED DESCRIPTION OF THE INVENTION

### First Embodiment

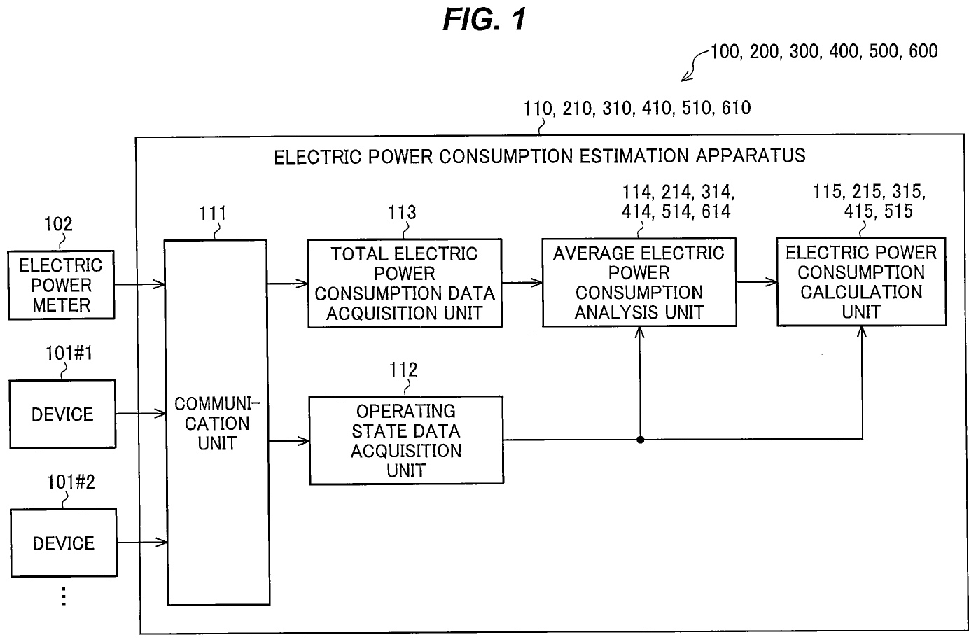

FIG. 1 is a block diagram schematically illustrating a configuration of an electric power consumption estimation system 100 including an electric power consumption estimation apparatus 110 according to a first embodiment.

The electric power consumption estimation system 100 includes a plurality of devices 101 #1, 101 #2, . . . an electric power meter 102, and the electric power consumption estimation apparatus 110.

The devices 101 #1, 101 #2, . . . are those in which electric power consumption is managed, such as home appliance devices in homes and factory automation (FA) devices in factories.

It is noted that when there is no need to particularly distinguish between the plurality of devices 101 #1, 101 #2, . . . , they are referred to as a device 101.

The device 101 transmits operating state data indicative of whether or not it is in an operating state to the electric power consumption estimation apparatus 110. The operating state data only needs to be data indicative of whether or not the device is in the operating state. Here, it is assumed that whether or not the device is in the operating state is represented by a binary value. For example, when the device 101 has a plurality of modes with different electric power consumptions, such as a normal mode and a power-saving mode in which an electric power consumption is smaller than that in the normal mode, the device 101 transmits data indicative of whether or not it is in the operating state for each mode to the electric power consumption estimation apparatus 110 as the operating state data. The electric power meter 102 measures the total electric power consumption, which is the sum of electric power consumptions of the plurality of devices 101 for each predetermined period, and transmits total electric power consumption data indicative of the total electric power consumption to the electric power consumption estimation apparatus 110.

The electric power consumption estimation apparatus 110 estimates a device electric power consumption, which is the electric power consumption of each of the plurality of devices 101, from the total electric power consumption indicated by the total electric power consumption data provided from the electric power meter 102.

The electric power consumption estimation apparatus 110 includes a communication unit 111, an operating state data acquisition unit 112, a total electric power consumption data acquisition unit 113, an average electric power consumption analysis unit 114, and an electric power consumption calculation unit 115.

The communication unit 111 communicates with the devices 101 and the electric power meter 102. For example, the communication unit 111 receives the operating state data from the device 101 and receives the total electric power consumption data from the electric power meter 102.

By way of example, the communication unit 111 is connected to a network not shown, such as a Local Area Network (LAN), and communicates with the device 101 and the electric power meter 102 connected to the network.

The operating state data acquisition unit 112 acquires operating state data from each of the plurality of devices 101 via the communication unit 111. The acquired operating state data is provided to the average electric power consumption analysis unit 114 and the electric power consumption calculation unit 115.

The total electric power consumption data acquisition unit 113 acquires the total electric power consumption data from the electric power meter 102 via the communication unit 111. The acquired total electric power consumption data is provided to the average electric power consumption analysis unit 114.

The average electric power consumption analysis unit 114 functions as an average electric power consumption estimation unit that estimates the average electric power consumption, which is an average of the electric power consumption of each of the plurality of devices 101, from the total electric power consumption of the plurality of devices 101 and whether or not each of the plurality of devices 101 is in the operating state. The average electric power consumption here is also referred to as an individual electric power consumption because this is the average electric power consumed by each individual device 101. Thus, the average electric power consumption analysis unit 114 is also referred to as an individual electric power consumption analysis unit or individual electric power consumption estimation unit.

The average electric power consumption analysis unit 114 in the first embodiment calculates an electric power consumption matrix from an equation; the equation states that the product of the electric power consumption matrix and a coefficient matrix results in an observation matrix, wherein the electric power consumption matrix has the average electric power consumption of each of the plurality of devices 101 as its components, the coefficient matrix has as its components values indicative of the plurality of devices 101 and of whether or not they are in the operating state corresponding to a predetermined period, and the observation matrix has the total electric power consumption corresponding to the period as its components.

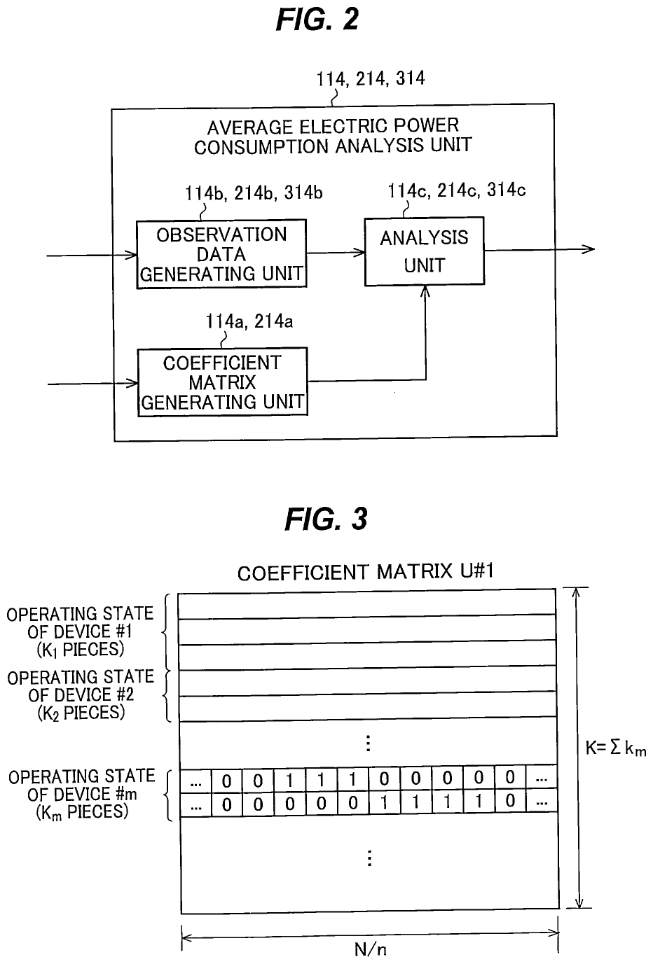

FIG. 2 is a block diagram schematically illustrating a configuration of the average electric power consumption analysis unit 114.

The average electric power consumption analysis unit 114 includes a coefficient matrix generating unit 114a, an observation data generating unit 114b, and an analysis unit 114c.

The coefficient matrix generating unit 114a generates a coefficient matrix U #1 indicative of whether or not the device 101 is in the operating state in a specific period n, for each device 101 or for each mode when the device 101 has a plurality of modes, in the interval N.

FIG. 3 is a schematic diagram illustrating an example of the coefficient matrix U #1 in the first embodiment.

The row of the coefficient matrix U #1 indicates whether or not the device is in the operating state in the specific period n for each device 101 or mode. Here, “1” indicates that the device is in the operating state, while “0” indicates that the device is not in the operating state. The operating state data indicative of whether or not the device 101 is in the operating state may be sent from the device 101 for each period n. The coefficient matrix generating unit 114a may sum values, each indicating whether or not the device is in the operating state, represented by the operating state data, for each period n. In order to sum the values, for example, a component of the matrix only needs to be set to “1” if the number of times of being in the operating state is greater than or equal to the number of times of being in a non-operating state during the period n. As described below, the period n is a period during which the electric power meter 102 measures the total electric power consumption.

The observation data generating unit 114b generates an observation matrix Y #1 that indicates the total electric power consumption for each period n in an interval N. In the first embodiment, the observation matrix Y #1 is a matrix with only one row, so that in the first embodiment, the observation matrix Y #1 is also referred to as an observation vector.

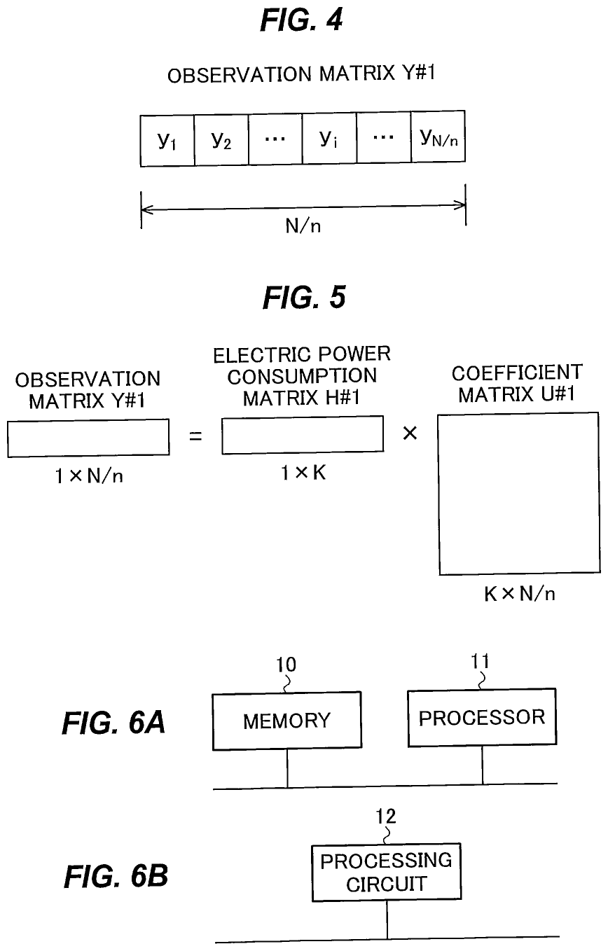

FIG. 4 is a schematic diagram illustrating an example of the observation matrix Y #1 in the first embodiment.

As illustrated in FIG. 4, the observation matrix Y #1 indicates the total electric power consumption of all the devices 101 for each period n in the interval N.

Here, the period n is a period during which the electric power meter 102 measures the total electric power consumption, for example, 1 minute, and can be set to any period.

The analysis unit 114c calculates an electric power consumption matrix H #1, which indicates the average electric power consumption for each period n in the period N, from the coefficient matrix U #1 provided from the coefficient matrix generating unit 114a and the observation matrix Y #1 provided from the observation data generating unit 114b.

FIG. 5 is a schematic diagram for explaining a calculation method of the electric power consumption matrix H #1 in the first embodiment.

As illustrated in FIG. 5, it can be considered that the total electric power consumption for each period n, indicated by the observation matrix Y #1, is represented by the product of the average electric power consumption for each period n, indicated by the electric power consumption matrix H #1, and a value indicative of whether or not the device is in the operating state for each period n, indicated by the coefficient matrix U #1.

Thus, when the analysis unit 114c can calculate an inverse matrix from the coefficient matrix U #1, it can calculate the electric power consumption matrix H #1 by multiplying both sides illustrated in FIG. 5 by the inverse matrix.

When the analysis unit 114c cannot calculate an inverse matrix from the coefficient matrix U #1, it can calculate the electric power consumption matrix H #1 by performing matrix factorization on the observation matrix Y #1 through use of the coefficient matrix U #1 as a constraint condition. Since the matrix factorization is a well-known technique, its detailed explanation is omitted.

The electric power consumption matrix H #1 calculated in this way is provided to the electric power consumption calculation unit 115 illustrated in FIG. 1.

The electric power consumption calculation unit 115 uses the average electric power consumption to calculate the device electric power consumption, which is the electric power consumption of each of the plurality of devices 101 for each predetermined period n. For example, the electric power consumption calculation unit 115 generates device electric power consumption time series data indicative of the device electric power consumption of each device 101 for each period n in the period N, from the electric power consumption matrix H #1 provided by the average electric power consumption analysis unit 114 and the operating state data provided by the operating state data acquisition unit 112.

For example, the electric power consumption calculation unit 115 can calculate the device electric power consumption in a certain period i included in the interval N by multiplying the average electric power consumption corresponding to the period i by a binary value indicative of whether or not the device is in the operating state corresponding to the period i. When the device 101 has a plurality of modes, the electric power consumption calculation unit 115 can calculate the device electric power consumption in the period i by multiplying the average electric power consumption corresponding to the period i for each mode by a binary value indicative of whether or not the device is in the operating state for each mode corresponding to the period i and then summing the multiplied values.

As illustrated in FIG. 6A, for example, parts or all of the operating state data acquisition unit 112, the total electric power consumption data acquisition unit 113, the average electric power consumption analysis unit 114, and the electric power consumption calculation unit 115 can be configured by a memory 10 and a processor 11 such as a Central Processing Unit (CPU) that executes a program stored in the memory 10. In other words, the electric power consumption estimation apparatus 110 can be implemented by a so-called computer. Such a program may be provided over a network or provided while being recorded on a recording medium. That is, such a program may be provided, for example, as a program product.

Also, as illustrated in FIG. 6B, for example, parts or all of the operating state data acquisition unit 112, the total electric power consumption data acquisition unit 113, the average electric power consumption analysis unit 114, and the electric power consumption calculation unit 115 can be configured by a processing circuit 12, such as a single circuit, a composite circuit, a programmed processor, a parallel programmed processor, an Application Specific Integrated Circuit (ASIC) or a Field Programmable Gate Array (FPGA).

As described above, the operating state data acquisition unit 112, the total electric power consumption data acquisition unit 113, the average electric power consumption analysis unit 114, and the electric power consumption calculation unit 115 can be configured by processing circuitry.

As described above, according to the first embodiment, by using the operating state data, the electric power consumption of each device 101 in its operating state can be determined with high accuracy even when the plurality of devices 101 with similar electric power consumption waveforms are included.

In addition, conventional techniques require sampling of a current waveform in at least a period of a power supply current, e.g., in a fine time period of less than 1/50 seconds for 50 Hz, and thus cannot use any general electric power meter in which a sampling period is normally one minute or more.

In contrast, according to the first embodiment, since the period n can be set arbitrarily, the device electric power consumption of each device 101 can be estimated from the total electric power consumption data measured in a predetermined time period. Thus, data from an inexpensive electric power meter can be used to reduce costs.

### Second Embodiment

Even when a given device 101 is in the same operating state, its electric power consumption may vary stochastically. In such a case, the device electric power consumption can be calculated more accurately when the estimation is performed by using a value obtained by averaging the total electric power consumption for each time frame T, which is a predetermined time unit longer than the period n during which the total electric power consumption is obtained. In the second embodiment, such a case is described.

As illustrated in FIG. 1, an electric power consumption estimation system 200 including an electric power consumption estimation apparatus 210 according to the second embodiment includes the plurality of devices 101, the electric power meter 102, and the electric power consumption estimation apparatus 210.

The device 101 and the electric power meter 102 of the electric power consumption estimation system 200 in the second embodiment are the same as the device 101 and the electric power meter 102 of the electric power consumption estimation system 100 in the first embodiment, respectively.

The electric power consumption estimation apparatus 210 estimates a device electric power consumption, which is the electric power consumption of each of the plurality of devices 101, from the total electric power consumption indicated by the total electric power consumption data from the electric power meter 102.

In the second embodiment, the electric power consumption estimation apparatus 210 calculates an electric power consumption matrix from an equation; the equation states that the product of the electric power consumption matrix and a coefficient matrix results in an observation matrix, wherein the electric power consumption matrix has an average electric power consumption of each of the plurality of devices 101 as its components, the coefficient matrix has as its components values obtained by averaging, over a time frame longer than a predetermined period, values indicative of the plurality of devices 101 and of whether or not they are in the operating state corresponding to the period, and the observation matrix has an average total electric power consumption obtained by averaging the total electric power consumptions in the periods included in the time frame as its components.

The electric power consumption estimation apparatus 210 includes the communication unit 111, the operating state data acquisition unit 112, the total electric power consumption data acquisition unit 113, an average electric power consumption analysis unit 214, and an electric power consumption calculation unit 215.

The communication unit 111, the operating state data acquisition unit 112, and the total electric power consumption data acquisition unit 113 of the electric power consumption estimation apparatus 210 according to the second embodiment are the same as the communication unit 111, the operating state data acquisition unit 112, and the total electric power consumption data acquisition unit 113 of the electric power consumption estimation apparatus 110 according to the first embodiment, respectively.

The average electric power consumption analysis unit 214 calculates the average electric power consumption, which is an average of the electric power consumption of each of all the devices 101, for each predetermined interval.

As illustrated in FIG. 2, the average electric power consumption analysis unit 214 includes a coefficient matrix generating unit 214a, an observation data generating unit 214b, and an analysis unit 214c.

The coefficient matrix generating unit 214a generates a coefficient matrix U #2 indicative of an average value regarding whether the device 101 is in the operating state in the time frame T longer than the period n, for each device 101 or for each mode when the device 101 has a plurality of modes, in the interval N.

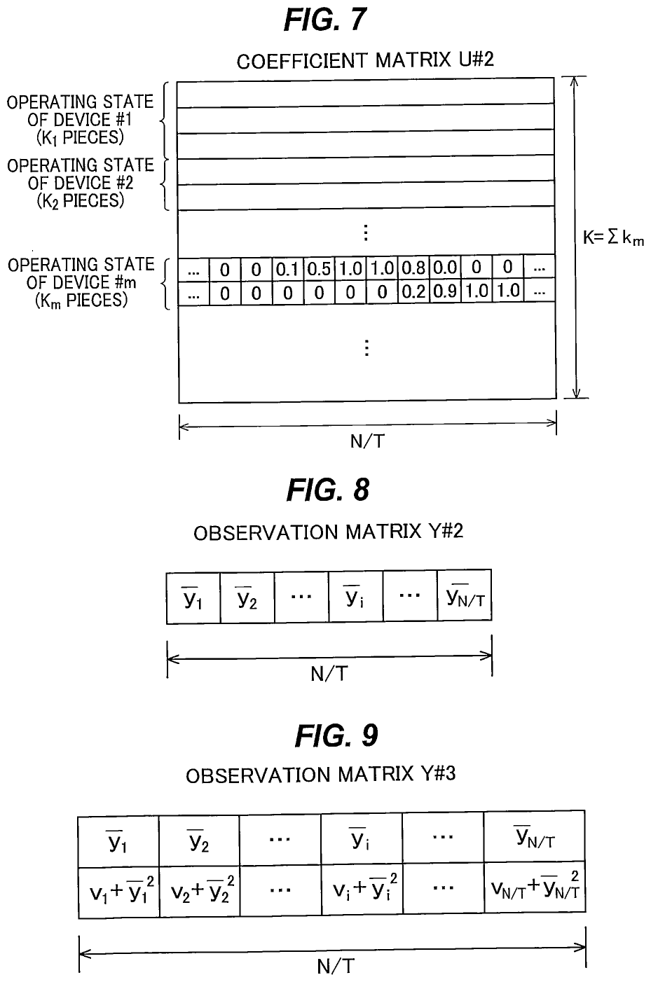

FIG. 7 is a schematic diagram illustrating an example of the coefficient matrix U #2 in the second embodiment.

The row of the coefficient matrix U #2 indicates an average value regarding whether or not the device is in the operating state in the predetermined time frame T for each device 101 or mode. When it can be determined whether or not the device is in the operating state for each period n, the average of values, i.e., “1” or “0”, indicative of whether or not the device is in the operating state for each period n included in the specific time frame T is stored in each row.

The observation data generating unit 214b generates an observation matrix Y #2 that indicates the average total electric power consumption for each time frame T longer than the period n in the interval N. Also, in the second embodiment, the observation matrix Y #2 is a matrix with only one row, so that in the second embodiment, the observation matrix Y #2 is also referred to as the observation vector.

FIG. 8 is a schematic diagram illustrating an example of the observation matrix Y #2 in the second embodiment.

As illustrated in FIG. 8, the observation matrix Y #2 indicates the average total electric power consumption of all the devices 101 for each time frame T in the interval N.

Here, also in the second embodiment, since the total electric power consumption data is transmitted from the electric power meter 102 for each period n, the observation data generating unit 214b calculates an average value of the total electric power consumptions indicated by the total electric power consumption data included in the specific time frame T as the average total electric power consumption in the time frame T.

The analysis unit 214c calculates an electric power consumption matrix H #2, which indicates the average electric power consumption for each time frame T in the period N, from the coefficient matrix U #2 provided from the coefficient matrix generating unit 214a and the observation matrix Y #2 provided from the observation data generating unit 214b. The calculation method here is the same as the calculation method in the first embodiment.

The electric power consumption matrix H #2 calculated in this way is provided to the electric power consumption calculation unit 215 illustrated in FIG. 1.

The electric power consumption calculation unit 215 generates device electric power consumption time series data indicative of the device electric power consumption of each device 101 for each period n in the interval N, from the electric power consumption matrix H #2 provided by the average electric power consumption analysis unit 214 and the operating state data provided by the operating state data acquisition unit 112.

For example, the electric power consumption calculation unit 215 can calculate the device electric power consumption in a certain period i included in the interval N by multiplying the average electric power consumption corresponding to the time frame T including the period i by the value indicative of whether or not the device is in the operating state corresponding to the period i. When the device 101 has a plurality of modes, the electric power consumption calculation unit 215 multiplies the average electric power consumption corresponding to the time frame T, including the period i, for each mode by the value indicative of whether or not the device is in the operating state for each mode corresponding to the period i, and it then sums these multiplied values, thereby making it possible to calculate the device electric power consumption in the period i.

As described above, according to the second embodiment, the device electric power consumption of each device 101 can be estimated stably with high accuracy even when electric power consumption fluctuates stochastically in the same operating state.

### Third Embodiment

In the device 101 that is even in the same operating state, its electric power consumption may fluctuate stochastically and vary in some cases. In such cases, it is preferable to estimate not only the average electric power consumption but also its variance in order to enable the calculation of the device electric power consumption with higher accuracy. In the third embodiment, these cases are described.

As illustrated in FIG. 1, an electric power consumption estimation system 300 including an electric power consumption estimation apparatus 310 according to the third embodiment includes the plurality of devices 101, the electric power meter 102, and the electric power consumption estimation apparatus 310.

The device 101 and the electric power meter 102 of the electric power consumption estimation system 300 in the third embodiment are the same as the device 101 and the electric power meter 102 of the electric power consumption estimation system 100 in the first embodiment, respectively.

The electric power consumption estimation apparatus 310 estimates a device electric power consumption, which is the electric power consumption of each of the plurality of devices 101, from the total electric power consumption indicated by the total electric power consumption data provided from the electric power meter 102.

The electric power consumption estimation apparatus 310 includes the communication unit 111, the operating state data acquisition unit 112, the total electric power consumption data acquisition unit 113, an average electric power consumption analysis unit 314, and an electric power consumption calculation unit 315.

The communication unit 111, the operating state data acquisition unit 112, and the total electric power consumption data acquisition unit 113 of the electric power consumption estimation apparatus 310 according to the third embodiment are the same as the communication unit 111, the operating state data acquisition unit 112, and the total electric power consumption data acquisition unit 113 of the electric power consumption estimation apparatus 110 according to the first embodiment, respectively.

The average electric power consumption analysis unit 314 calculates the average electric power consumption, which is an average of the electric power consumption of each of all the devices 101, for each predetermined interval, and its variance as well.

In the third embodiment, the average electric power consumption analysis unit 314 calculates an electric power consumption matrix from an equation; the equation states that the product of the electric power consumption matrix and a coefficient matrix results in an observation matrix, wherein the electric power consumption matrix has an average electric power consumption of each of the plurality of devices 101 and a variance of the electric power consumption of each of the plurality of devices 101 as its components, the coefficient matrix has as its components values obtained by averaging, over a time frame longer than a predetermined period, values indicative of the plurality of devices 101 and of whether or not they are in the operating state corresponding to the predetermined period, and the observation matrix has as its components an average total electric power consumption obtained by averaging the total electric power consumptions in the periods included in the time frame and the sum of the square of the average total electric power consumption and the sample variance of the total electric power consumption in the time frame.

As illustrated in FIG. 2, the average electric power consumption analysis unit 314 includes a coefficient matrix generating unit 214a, an observation data generating unit 314b, and an analysis unit 314c.

The coefficient matrix generating unit 214a of the average electric power consumption analysis unit 314 in the third embodiment is the same as the coefficient matrix generating unit 214a of the average electric power consumption analysis unit 214 in the second embodiment.

The observation data generating unit 314b generates an observation matrix Y #3 that has the average total electric power consumption for each time frame T as a first row component, as well as the sum of the square of the average total electric power consumption and the sample variance of the total electric power consumption for each time frame T as a second row component, in the period N.

FIG. 9 is a schematic diagram illustrating an example of the observation matrix Y #3 in the third embodiment.

As illustrated in FIG. 9, the observation matrix Y #3 has the average total electric power consumption of all devices 101 for each time frame T in the first row, as well as the sum of the square of the average total electric power consumption and the sample variance of the total electric power consumption of all devices 101 for each time frame T in the second row, in the period N.

The analysis unit 314c calculates an electric power consumption matrix H #3, which indicates the average electric power consumption and its variance of the electric power consumption, for each time frame T in the period N, from the coefficient matrix U #2 provided from the coefficient matrix generating unit 214a and the observation matrix Y #3 provided from the observation data generating unit 314b.

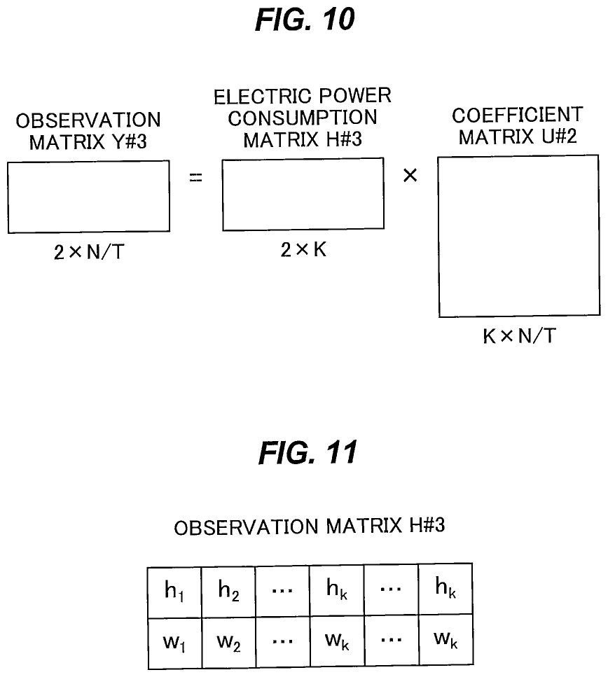

FIG. 10 is a schematic diagram for explaining a calculation method of the electric power consumption matrix H #3 in the third embodiment.

As illustrated in FIG. 10, it can be considered that the average total electric power consumption and the sum for each time frame T, indicated by the observation matrix Y #3, are represented by the product of the average electric power consumption and the variance for each time frame T, indicated by the electric power consumption matrix H #3, and the value indicative of whether or not the device is in the operating state for each time frame T, indicted by the coefficient matrix U #2.

Thus, when the analysis unit 314c can calculate an inverse matrix from the coefficient matrix U #2, it can calculate the electric power consumption matrix H #3 by multiplying both sides illustrate in FIG. 10 by the inverse matrix.

When the analysis unit 314c cannot calculate an inverse matrix from the coefficient matrix U #2, it can calculate the electric power consumption matrix H #3 by performing matrix factorization on the observation matrix Y #3 through use of the coefficient matrix U #2 as a constraint condition.

FIG. 11 is a schematic diagram illustrating an example of the electric power consumption matrix H #3 in the third embodiment.

The electric power consumption matrix H #3 stores, for each time frame T, an estimated value of the average electric power consumption in the first row and an estimated value of the variance in the second row.

The electric power consumption matrix H #3 calculated in this way is provided to the electric power consumption calculation unit 315 illustrated in FIG. 1.

The electric power consumption calculation unit 315 generates the device electric power consumption time series data indicative of the device electric power consumption of each device 101 for each period n in the interval N, from the electric power consumption matrix H #3 provided by the average electric power consumption analysis unit 314 and the operating state data provided by the operating state data acquisition unit 112.

For example, the electric power consumption calculation unit 315 multiplies the average electric power consumption corresponding to the time frame T that includes a certain period i included in the interval N by the value indicative of whether or not the device is in the operating state corresponding to the period i, and it then adds to this obtained value, a value which becomes larger as the variance value corresponding to the time frame T including the period i increases, thereby making it possible to calculate the device electric power consumption in the period i. The value added here can be a value obtained by multiplying the square root of the variance by a predetermined coefficient, by way of example.

When the device 101 has a plurality of modes, the electric power consumption calculation unit 315 multiplies the average electric power consumption corresponding to the time frame T that includes the period i for each mode by the value indicative of whether or not the device is in the operating state for each mode corresponding to the period i, then adds to this obtained value, a value which becomes larger as the variance value corresponding to the time frame T including the period i increases, and eventually sums these calculated values, thereby making it possible to calculate the device electric power consumption in the period i.

As described above, according to the third embodiment, since the variance value of each device 101 can be estimated, it becomes possible to ascertain the electric power consumption that reflects the fluctuations in the electric power consumption of each device 101.

### Fourth Embodiment

Even when the device 101 is in the same operating state, its statistical value of the electric power consumption (e.g., average value or variance) may fluctuate stochastically as the time elapses. A fourth embodiment addresses such cases.

As illustrated in FIG. 1, an electric power consumption estimation system 400 including an electric power consumption estimation apparatus 410 according to the fourth embodiment includes the plurality of devices 101, the electric power meter 102, and the electric power consumption estimation apparatus 410.

The device 101 and the electric power meter 102 of the electric power consumption estimation system 400 in the fourth embodiment are the same as the device 101 and the electric power meter 102 of the electric power consumption estimation system 100 in the first embodiment, respectively.

The electric power consumption estimation apparatus 410 estimates a device electric power consumption, which is the electric power consumption of each of the plurality of devices 101, from the total electric power consumption indicated by the total electric power consumption data provided from the electric power meter 102.

The electric power consumption estimation apparatus 410 includes the communication unit 111, the operating state data acquisition unit 112, the total electric power consumption data acquisition unit 113, an average electric power consumption analysis unit 414, and an electric power consumption calculation unit 415.

The communication unit 111, the operating state data acquisition unit 112, and the total electric power consumption data acquisition unit 113 of the electric power consumption estimation apparatus 410 according to the fourth embodiment are the same as the communication unit 111, the operating state data acquisition unit 112, and the total electric power consumption data acquisition unit 113 of the electric power consumption estimation apparatus 110 according to the first embodiment, respectively.

The average electric power consumption analysis unit 414 calculates the average electric power consumption, which is an average of the electric power consumption of each of all the devices 101, for each predetermined interval.

In the fourth embodiment, when the operating state of each of the plurality of devices 101 or the operating state indicated by one mode included in the plurality of modes continues for a predetermined threshold value or more, the average electric power consumption analysis unit 414 generates a coefficient matrix by using an operating state during an interval up to the predetermined threshold value as one mode, and an operating state during an interval following the predetermined interval as another mode.

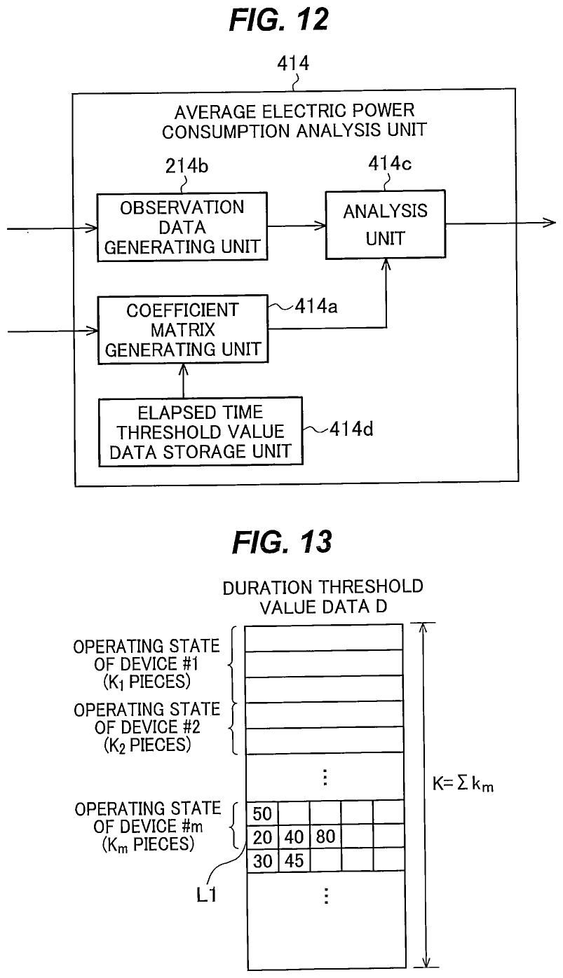

FIG. 12 is a block diagram schematically illustrating a configuration of the average electric power consumption analysis unit 414 in the fourth embodiment.

As illustrated in FIG. 12, the average electric power consumption analysis unit 414 includes a coefficient matrix generating unit 414a, the observation data generating unit 214b, the analysis unit 214c, and an elapsed time threshold value data storage unit 414d.

The observation data generating unit 214b and the analysis unit 214c of the average electric power consumption analysis unit 414 in the fourth embodiment are the same as the observation data generating unit 214b and the analysis unit 214c of the average electric power consumption analysis unit 214 in the second embodiment.

The elapsed time threshold value data storage unit 414d stores elapsed time threshold value data, which indicates the threshold value of an elapsed time to be treated as another mode if its operating state continues, for each device 101 or for each mode when the device 101 has a plurality of modes.

FIG. 13 is a schematic diagram illustrating an example of duration threshold value data.

As illustrated in FIG. 13, duration threshold value data D contains in each row, a threshold value of the elapsed time for each device 101 or for each mode when the device 101 has a plurality of modes.

For example, in a row L1, it indicates that when the elapsed time reaches “20”, the device or the one mode is switched to another mode; when the elapsed time reaches “40”, it is switched to yet another mode; and when the elapsed time reaches “80”, it is switched to further another mode.

The coefficient matrix generating unit 414a generates a coefficient matrix U #4 indicative of an average operating state in a long time frame T for each device 101 or for each mode when the device 101 has a plurality of modes, in the interval N.

Here, in the fourth embodiment, the coefficient matrix generating unit 414a generates the coefficient matrix U #4 such that the operating state of the device 101 or mode of the device 101 is switched to another mode when it reaches the corresponding threshold value or more, indicated by the elapsed time threshold value data, by referring to the elapsed time threshold value data stored in the elapsed time threshold value data storage unit 414d.

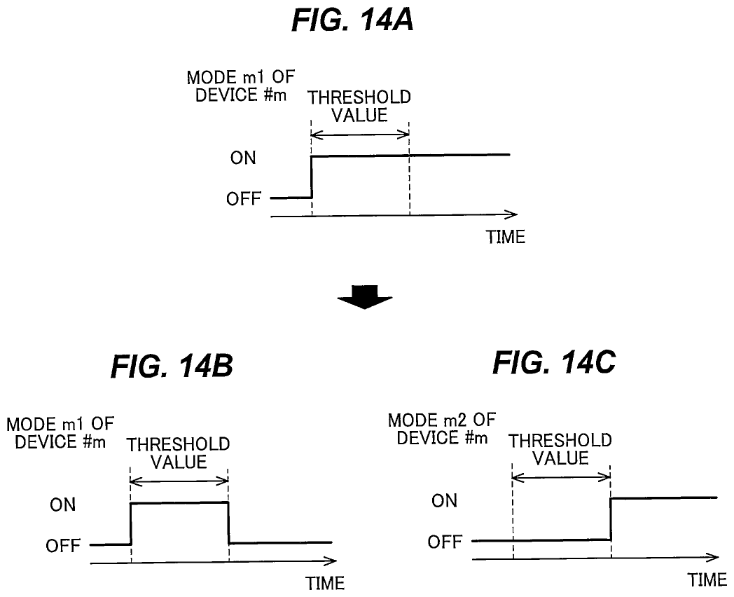

FIGS. 14A to 14C are schematic diagrams for explaining the processing in which the coefficient matrix generating unit 414a compares the elapsed time in the operating state with the threshold value to generate another mode.

When the operating state of a certain mode m1 of a device 101 #m reaches the corresponding threshold value or more as illustrated in FIG. 14A, the coefficient matrix generating unit 414a changes the mode m1 to a non-operating state at the elapsed time of the threshold value as illustrated in FIG. 14B.

The coefficient matrix generating unit 414a then generates another mode m2 that is brought into an operating state after the elapsed time corresponding to the threshold value as illustrated in FIG. 14C.

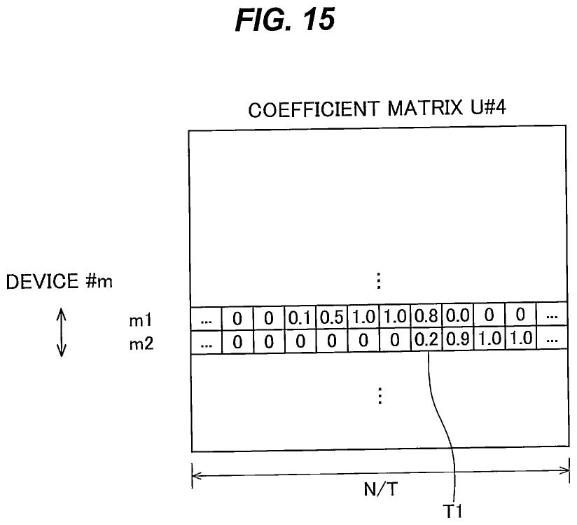

FIG. 15 is a schematic diagram illustrating an example of the coefficient matrix U #4 generated in the manner described above.

In the coefficient matrix U #4, the mode m2 of the device 101 #m is divided from the mode m1 in a specific time frame T1.

The coefficient matrix U #4 generated in the manner described above is provided to the analysis unit 214c together with the duration threshold value data D. The processing performed in the analysis unit 214c is the same as that in the second embodiment, except that the number of modes may be increased. The analysis unit 214 provides the duration threshold value data D to the electric power consumption calculation unit 415 together with a generated electric power consumption matrix H #4.

The electric power consumption calculation unit 415 compares the duration of the operating state indicated by the operating state data provided by the operating state data acquisition unit 112, with the corresponding threshold value indicated by the duration threshold value data D provided by the analysis unit 214c, thereby performing mode division as necessary in the same manner as the coefficient matrix generating unit 414a.

Then, the electric power consumption calculation unit 415 generates device electric power consumption time series data indicative of the device electric power consumption of each device 101 for each period n in the interval N by using the electric power consumption matrix H #4 provided by the average electric power consumption analysis unit 214 and the operating state with the modes divided as necessary. The processing of calculating the device electric power consumption is the same as that in the second embodiment, except that the number of modes may increase.

As described above, according to the fourth embodiment, in a case where there is a device 101 that has its electric power consumption statistics fluctuating over the elapsed time even in the same operating state, the device 101 can be treated as being in a different mode based on the predetermined threshold value, which allows for the estimation of electric power consumption with higher accuracy.

### Fifth Embodiment

A plurality of devices 101 may include a device 101 whose operating state data cannot be acquired. A fifth embodiment addresses such cases.

As illustrated in FIG. 1, an electric power consumption estimation system 500 including an electric power consumption estimation apparatus 510 according to the fifth embodiment includes the plurality of devices 101, the electric power meter 102, and the electric power consumption estimation apparatus 510.

The device 101 and the electric power meter 102 of the electric power consumption estimation system 500 in the fifth embodiment are the same as the device 101 and the electric power meter 102 of the electric power consumption estimation system 100 in the first embodiment, respectively.

The electric power consumption estimation apparatus 510 estimates the device electric power consumption, which is the electric power consumption of each of the plurality of devices 101, from the total electric power consumption indicated by the total electric power consumption data provided from the electric power meter 102.

The electric power consumption estimation apparatus 510 includes the communication unit 111, the operating state data acquisition unit 112, the total electric power consumption data acquisition unit 113, an average electric power consumption analysis unit 514, and an electric power consumption calculation unit 515.

The communication unit 111, the operating state data acquisition unit 112, and the total electric power consumption data acquisition unit 113 of the electric power consumption estimation apparatus 510 according to the fifth embodiment are the same as the communication unit 111, the operating state data acquisition unit 112, and the total electric power consumption data acquisition unit 113 of the electric power consumption estimation apparatus 110 according to the first embodiment, respectively.

The average electric power consumption analysis unit 514 calculates the average electric power consumption, which is an average of the electric power consumption of each of all the devices 101, for each predetermined interval.

In a case where there is an unknown device 101 among the plurality of devices 101 that does not transmit its operating state data, the average electric power consumption analysis unit 514 in the fifth embodiment is designed to include in the coefficient matrix, a component that shows a value indicative of whether or not the unknown device is in a predetermined operating state, as a value indicative of whether or not the unknown device is in the operating state.

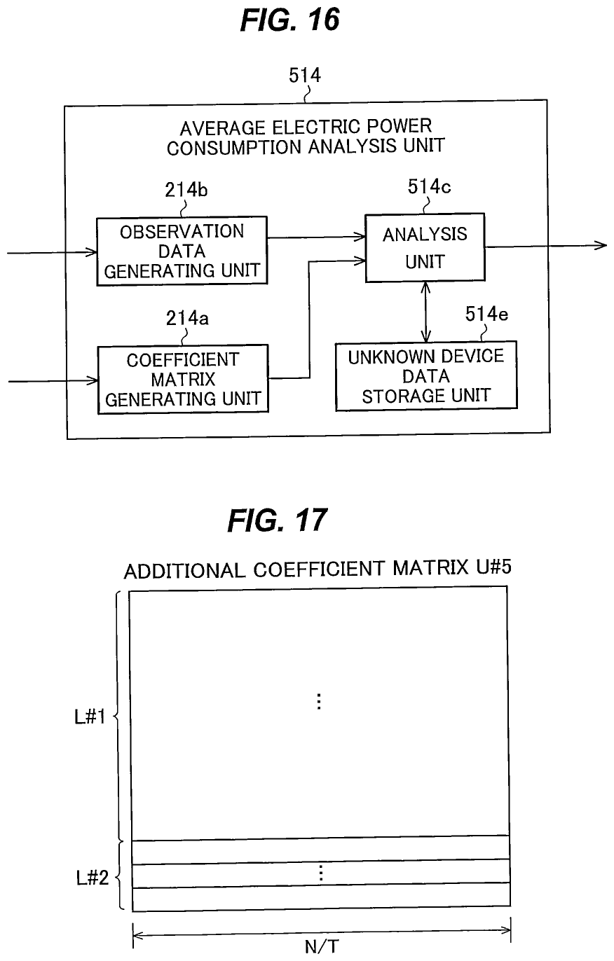

FIG. 16 is a block diagram schematically illustrating a configuration of the average electric power consumption analysis unit 514 in the fifth embodiment.

As illustrated in FIG. 16, the average electric power consumption analysis unit 514 includes the coefficient matrix generating unit 214a, the observation data generating unit 214b, an analysis unit 514c, and an unknown device data storage unit 514e.

The coefficient matrix generating unit 214a and the observation data generating unit 214b of the average electric power consumption analysis unit 514 in the fifth embodiment are the same as the coefficient matrix generating unit 214a and the observation data generating unit 214b of the average electric power consumption analysis unit 214 in the second embodiment, respectively.

The unknown device data storage unit 514e stores unknown device data indicative of whether or not an unknown device 101 whose operating state data cannot be acquired among the plurality of devices 101 is in the operating state.

For example, an operator of the electric power consumption estimation apparatus 510 only needs to store in advance in the unknown device data storage unit 514e, unknown device identification information, which is identification information that can identify the unknown device, and data indicative of whether or not the unknown device is in the operating state, as the unknown device data. Whether or not the unknown device is in the operating state here is indicated by a binary value, and its contents can be arbitrary.

The analysis unit 514c calculates the electric power consumption matrix H #2, which indicates the average electric power consumption for each time frame T in the period N, from the coefficient matrix U #2 provided from the coefficient matrix generating unit 214a and the observation matrix Y #2 provided from the observation data generating unit 214b.

The electric power consumption matrix H #2 calculated in this way is provided to the electric power consumption calculation unit 515.

In the fifth embodiment, when unknown device data is stored in the unknown device data storage unit 514e, the analysis unit 514c generates an additional coefficient matrix U #5 by adding a row corresponding to whether or not the unknown device is in the operating state, to the coefficient matrix U #2. The analysis unit 514c then calculates an additional electric power consumption matrix H #5, which indicates the average electric power consumption for each time frame T in the interval N, from the additional coefficient matrix U #5 and the observation matrix Y #2 provided from the observation data generating unit 214b. The additional electric power consumption matrix H #5 also includes the average electric power consumption of the unknown device.

FIG. 17 is a schematic diagram illustrating an example of the additional electric power consumption matrix H #5.

The additional electric power consumption matrix H #5 includes a row L #1 corresponding to whether or not the device 101, whose operating state data can be acquired, is in the operating state, and a row L #2 corresponding to whether or not the unknown device is in the operating state.

Here, the analysis unit 514c updates whether or not the unknown device is in the operating state, as indicated by the unknown device data, such that the result of multiplying the additional electric power consumption matrix H #5 by the additional coefficient matrix U #5 becomes closer to the observation matrix Y #2. The analysis unit 514c then continues updating whether or not the unknown device is in the operating state, as indicated by the unknown device data, until a predetermined convergence condition is satisfied, and ultimately calculates the final additional electric power consumption matrix H #5.

The convergence condition here is, for example, a condition in which the number of times of updating reaches an update threshold value, which is the threshold value, or a condition in which a difference between the result of multiplying the additional electric power consumption matrix H #5 by the additional coefficient matrix U #5 and the observation matrix Y #2 is less than or equal to a predetermined threshold value.

The additional electric power consumption matrix H #5 calculated in this way is provided to the electric power consumption calculation unit 515 together with the unknown device data.

The electric power consumption calculation unit 515 generates the device electric power consumption time series data indicative of the device electric power consumption of each device 101 for each period n in the interval N, based on the electric power consumption matrix H #2 when the electric power consumption matrix H #2 is provided by the average electric power consumption analysis unit 514 and on the operating state data provided from the operating state data acquisition unit 112. The processing here is the same as the processing in the electric power consumption calculation unit 215 in the second embodiment.

The electric power consumption calculation unit 515 generates the additional device electric power consumption time series data indicative of the device electric power consumption of each device 101 for each period n in the interval N, based on the additional electric power consumption matrix H #5 when the additional electric power consumption matrix H #5 is provided from the average electric power consumption analysis unit 514, on the unknown device data provided together with the additional electric power consumption matrix H #5, and on the operating state data provided from the operating state data acquisition unit 112. The processing here is the same as the processing in the electric power consumption calculation unit 215 in the second embodiment, except that it includes processing about whether or not the unknown device is in the operating state.

As described above, according to the fifth embodiment, the device electric power consumption of each device 101 can be estimated even when there is a device 101 whose operating state data cannot be acquired.

### Sixth Embodiment

Regarding the electric power consumptions of the plurality of devices 101, once their reliable results are obtained, it is considered that they will not change so much unless the environment varies significantly. A sixth embodiment addresses such cases.

As illustrated in FIG. 1, an electric power consumption estimation system 600 including an electric power consumption estimation apparatus 610 according to a sixth embodiment includes the plurality of devices 101, the electric power meter 102, and the electric power consumption estimation apparatus 610.

The device 101 and the electric power meter 102 of the electric power consumption estimation system 600 in the sixth embodiment are the same as the device 101 and the electric power meter 102 of the electric power consumption estimation system 100 in the first embodiment, respectively.

The electric power consumption estimation apparatus 610 estimates a device electric power consumption, which is the electric power consumption of each of the plurality of devices 101, from the total electric power consumption indicated by the total electric power consumption data provided from the electric power meter 102.

The electric power consumption estimation apparatus 610 includes the communication unit 111, the operating state data acquisition unit 112, the total electric power consumption data acquisition unit 113, an average electric power consumption analysis unit 614, and the electric power consumption calculation unit 215.

The communication unit 111, the operating state data acquisition unit 112, and the total electric power consumption data acquisition unit 113 of the electric power consumption estimation apparatus 610 according to the sixth embodiment are the same as the communication unit 111, the operating state data acquisition unit 112, and the total electric power consumption data acquisition unit 113 of the electric power consumption estimation apparatus 110 according to the first embodiment, respectively.

The electric power consumption calculation unit 215 of the electric power consumption estimation apparatus 610 according to the sixth embodiment is the same as the electric power consumption calculation unit 215 of the electric power consumption estimation apparatus 210 according to the second embodiment.

The average electric power consumption analysis unit 614 calculates the average electric power consumption, which is an average of the electric power consumption of each of all the devices 101, for each predetermined interval.

The average electric power consumption analysis unit 614 in the sixth embodiment sequentially calculates the electric power consumption matrices and stops calculating a new electric power consumption matrix when the electric power consumption matrices satisfy a predetermined convergence condition.

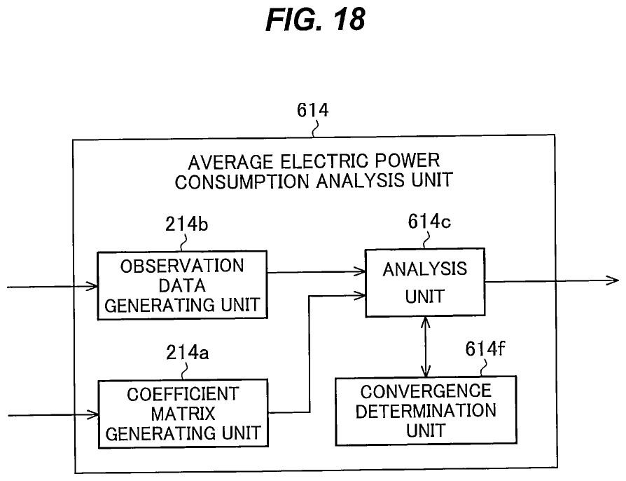

FIG. 18 is a block diagram schematically illustrating a configuration of the average electric power consumption analysis unit 614 in the sixth embodiment.

As illustrated in FIG. 18, the average electric power consumption analysis unit 614 includes the coefficient matrix generating unit 214a, the observation data generating unit 214b, an analysis unit 614c, and a convergence determination unit 614f.

The coefficient matrix generating unit 214a and the observation data generating unit 214b of the average electric power consumption analysis unit 614 in the sixth embodiment are the same as the coefficient matrix generating unit 214a and the observation data generating unit 214b of the average electric power consumption analysis unit 214 of the second embodiment, respectively.

As in the second embodiment, the analysis unit 614c calculates the electric power consumption matrix H #2, which indicates the average electric power consumption for each time frame T in the period N, from the coefficient matrix U #2 provided from the coefficient matrix generating unit 214a and the observation matrix Y #2 provided from the observation data generating unit 214b.

The electric power consumption matrix H #2 calculated in this way is provided to the convergence determination unit 614f and the electric power consumption calculation unit 215 illustrated in FIG. 1.

When an instructed is given by the convergence determination unit 614f, the analysis unit 614c stops calculating a new electric power consumption matrix H #2 and provides the last calculated electric power consumption matrix H #2 to the electric power consumption calculation unit 215.

The convergence determination unit 614f receives the electric power consumption matrix H #2 from the analysis unit 614c and determines whether or not the convergence condition is satisfied. The convergence condition here is, for example, a case in which the number of times that a difference between a newly obtained electric power consumption matrix H #2 and a previously obtained electric power consumption matrix H #2 is less than or equal to a convergence threshold value, which is a predetermined threshold value, becomes more than or equal to a count threshold value, which is a continuous predetermined threshold value, or a case in which the number of times that the electric power consumption matrix H #2 is calculated is more than or equal to a convergence count threshold value, which is a predetermined threshold value. It is noted that, for example, the electric power consumption matrix H #2 obtained immediately before the newly obtained electric power consumption matrix H #2 can be used as the previously obtained the electric power consumption matrix H #2.

Then, when the convergence condition is satisfied, the convergence determination unit 614f instructs the analysis unit 614c to stop calculating.

As described above, according to the sixth embodiment, the calculation cost of the electric power consumption estimation apparatus 610 is reduced.

In the third to sixth embodiments described above, the processing is performed according to the time frame T described in the second embodiment, but the third to sixth embodiments are not limited to such examples. For example, the third to sixth embodiments may also perform the processing according to the period n described in the first embodiment.

### Seventh Embodiment

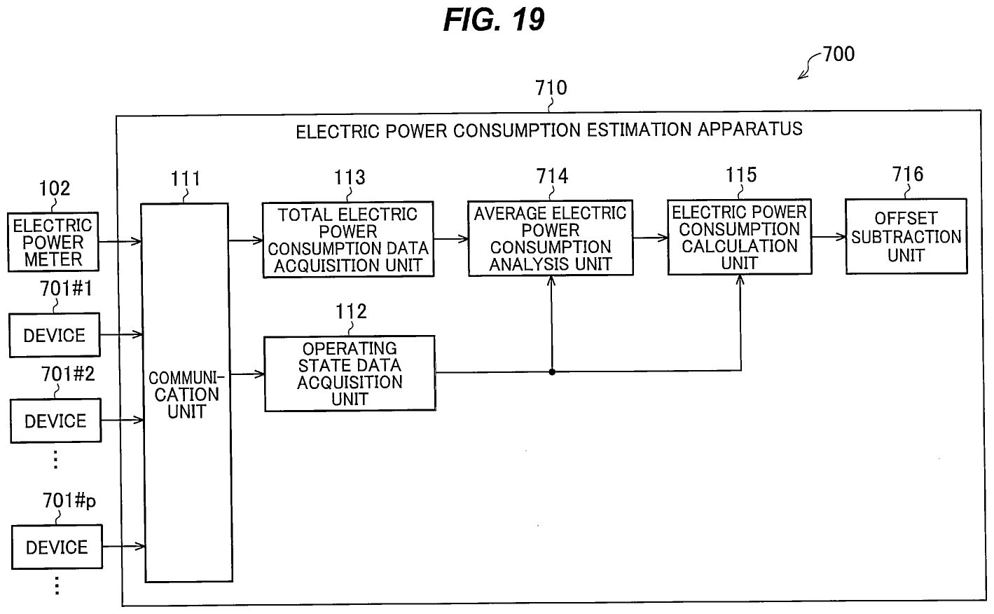

FIG. 19 is a block diagram schematically illustrating a configuration of an electric power consumption estimation system 700 including an electric power consumption estimation apparatus 710 according to a seventh embodiment.

The electric power consumption estimation system 700 includes a plurality of devices 701 #1, 701 #2, . . . , the electric power meter 102, and the electric power consumption estimation apparatus 710.

The electric power meter 102 of the electric power consumption estimation system 700 in the seventh embodiment is the same as the electric power meter 102 of the electric power consumption estimation system 100 in the first embodiment.

The devices 701 #1, 701 #2, . . . are those in which electric power consumption is managed, such as home appliance devices in homes and FA devices in factories. In the seventh embodiment, it is assumed that the plurality of devices 701 #1, 701 #2, . . . include a device 701 #p corresponding to an electric power generating device that generates electric power.

In addition, when there is no need to particularly distinguish between the plurality of devices 701 #1, 701 #2, . . . 701 #p, they are referred to as a device 701.

The device 701 transmits operating state data indicative of whether or not it is in an operating state to the electric power consumption estimation apparatus 710. The operating state data only needs to be data indicative of whether or not the device is in the operating state. For example, when the device 701 has a plurality of modes with different electric power consumptions, such as a normal mode and a power-saving mode in which an electric power consumption is smaller than that in the normal mode, the device 701 transmits data indicative of whether or not it is in the operating state for each mode to the electric power consumption estimation apparatus 710 as the operating state data.

Here, the device 701 #p corresponding to the electric power generating device generates electric power when it is in the operating state and stops generating electric power when it is not in the operating state. Thus, from the perspective of electric power consumption, the device 701 #p corresponding to the electric power generating device is a device that exhibits a negative electric power consumption in the operating state and an electric power consumption of “0” when it is not in the operating state.

The matrix factorization used in the electric power consumption estimation systems 100 to 600 described in the first to sixth embodiments assumes that all matrix elements are non-negative values. Thus, as described above, when the devices 701 include the device 701 #p corresponding to the electric power generating device, the electric power consumption estimation systems 100 to 600 described in the first to sixth embodiments cannot estimate electric power consumption. For this reason, the seventh embodiment can estimate electric power consumption even when the devices 701 include the device 701 #p that corresponds to the electric power generating device.

The electric power consumption estimation apparatus 710 estimates the device electric power consumption, which is an electric power consumption of each of the plurality of devices 701, from the total electric power consumption indicated by the total electric power consumption data provided from the electric power meter 102.

The electric power consumption estimation apparatus 710 includes the communication unit 111, the operating state data acquisition unit 112, the total electric power consumption data acquisition unit 113, an average electric power consumption analysis unit 714, the electric power consumption calculation unit 115, and an offset subtraction unit 716.

The communication unit 111, the operating state data acquisition unit 112, the total electric power consumption data acquisition unit 113, and the electric power consumption calculation unit 115 of the electric power consumption estimation apparatus 710 in the seventh embodiment are the same as the communication unit 111, the operating state data acquisition unit 112, the total electric power consumption data acquisition unit 113, and the electric power consumption calculation unit 115 of the electric power consumption estimation apparatus 110 in the first embodiment, respectively.

It is noted that the electric power consumption calculation unit 115 provides the generated device electric power consumption time series data to the offset subtraction unit 716.

As in the first embodiment, the average electric power consumption analysis unit 714 functions as an average electric power consumption estimation unit that estimates an individual electric power consumption, which is an average of electric power consumption of each of the plurality of devices 701, from the total electric power consumption of the plurality of devices 701 and whether or not each of the plurality of devices 701 is in the operating state. However, in the seventh embodiment, since the devices 701 include the device 701 #p corresponding to the electric power generating device that has a negative electric power consumption, the average electric power consumption analysis unit 714 adds an offset value to the total electric power consumption so as to prevent the amount of electric power generated by the device 701 #p corresponding to the electric power generating device from becoming negative. For example, the average electric power consumption analysis unit 714 adds a predetermined offset value to the total electric power consumption. The average electric power consumption analysis unit 714 then estimates the average electric power consumption of each of the plurality of devices 701 from the total electric power consumption to which the offset value is added and whether or not they are in the operating state. The offset value is desirably greater than or equal to the amount of electric power generated by the device 701 #p corresponding to the electric power generating device in the predetermined period.

Specifically, the average electric power consumption analysis unit 714 calculates an electric power consumption matrix from an equation; the equation states that the product of the electric power consumption matrix and a coefficient matrix results in an observation matrix, wherein the electric power consumption matrix has an average electric power consumption of each of the plurality of devices 701 as its components, the coefficient matrix has as its components values indicative of the plurality of devices 701 and of whether or not they are in the operating state corresponding to a predetermined period, and the observation matrix has the total electric power consumption corresponding to the period as its component. In the seventh embodiment, the average electric power consumption analysis unit 714 inverts the value of whether or not the device 701 #p corresponding to the electric power generating device is in the coefficient matrix from the operating state data.

The details thereof will be described below.

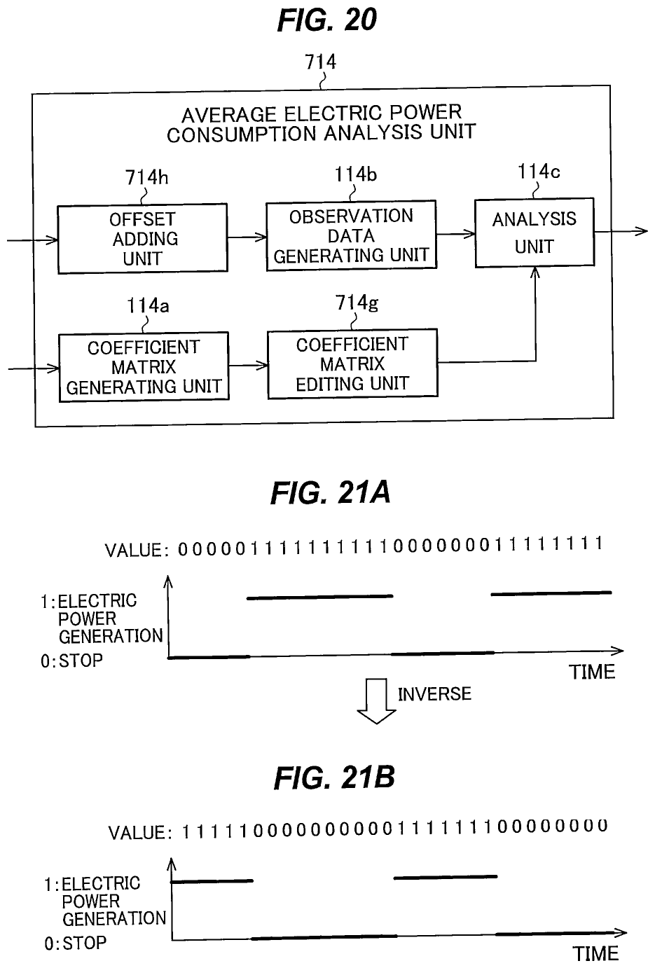

FIG. 20 is a block diagram schematically illustrating a configuration of the average electric power consumption analysis unit 714.

The average electric power consumption analysis unit 714 includes the coefficient matrix generating unit 114a, the observation data generating unit 114b, the analysis unit 114c, a coefficient matrix editing unit 714g, and an offset adding unit 714h.

The coefficient matrix generating unit 114a, the observation data generating unit 114b, and the analysis unit 114c of the average electric power consumption analysis unit 714 in the seventh embodiment are the same as the coefficient matrix generating unit 114a, the observation data generating unit 114b, and the analysis unit 114c of the average electric power consumption analysis unit 114 in the first embodiment, respectively.

However, the coefficient matrix generating unit 114a provides the generated coefficient matrix to the coefficient matrix editing unit 714g.

The observation data generating unit 114b uses the added total electric power consumption data indicative of the total electric power consumption to which an offset is added by the offset adding unit 714h to generate an observation matrix indicative of the total electric power consumption to which the offset value is added for each period n.

The analysis unit 114c receives an edited coefficient matrix from the coefficient matrix editing unit 714g and calculates the electric power consumption matrix from the edited coefficient matrix and the observation matrix. The analysis unit 114c then provides the calculated electric power consumption matrix to the offset subtraction unit 716.

In a row vector indicative of an operating state of the device 701 #p, which corresponds to the electric power generating device, included in a coefficient matrix provided from the coefficient matrix generating unit 114a, the coefficient matrix editing unit 714g edits the operating state indicating that the device is generating electric power to “0”, whereas it edits the non-operating state indicating that the device is not generating electric power to “1”.

Specifically, as illustrated in FIG. 21B, the coefficient matrix editing unit 714g inverts the values of “0” and “1” in the row vector indicating the operating state of the device 701 #p, which corresponds to the electric power generating device, in the coefficient matrix provided from the coefficient matrix generating unit 114a illustrated in FIG. 21A.

The coefficient matrix editing unit 714g provides the edited coefficient matrix, which is the coefficient matrix edited in the above manner, to the analysis unit 114c.

The offset adding unit 714h adds an offset value to the total electric power consumption indicated by the total electric power consumption data provided from the total electric power consumption data acquisition unit 113; the offset value is greater than or equal to the negative electric power consumption, which is the amount of electric power generated by the device 701 #p corresponding to the electric power generating device in the period n. Here, the offset value is assumed to be predetermined based on the amount of electric power generated by the device 701 #p corresponding to the electric power generating device in the period n.

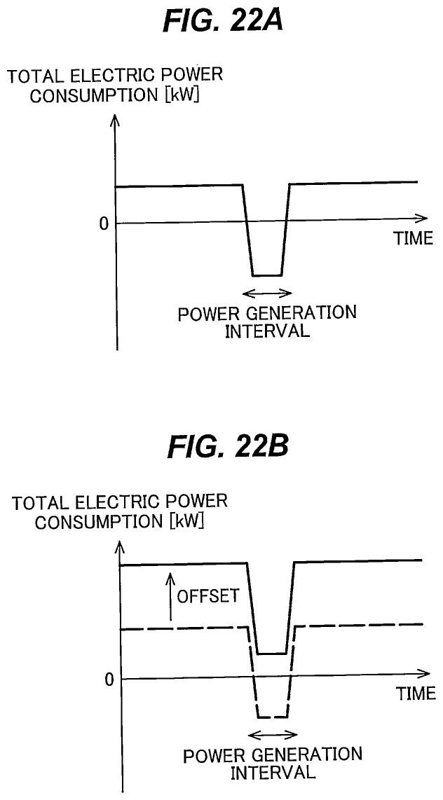

For example, as illustrated in FIG. 22A, even when the device 701 #p, which corresponds to the electric power generating device, generates electric power during a power generation interval which becomes a negative total electric power consumption, adding the offset value renders the total electric power consumption non-negative, as illustrated in FIG. 22B.

The offset adding unit 714h then provides added total electric power consumption data, indicative of the added total electric power consumption, which is the total electric power consumption with the offset added thereto, to the observation data generating unit 114b.

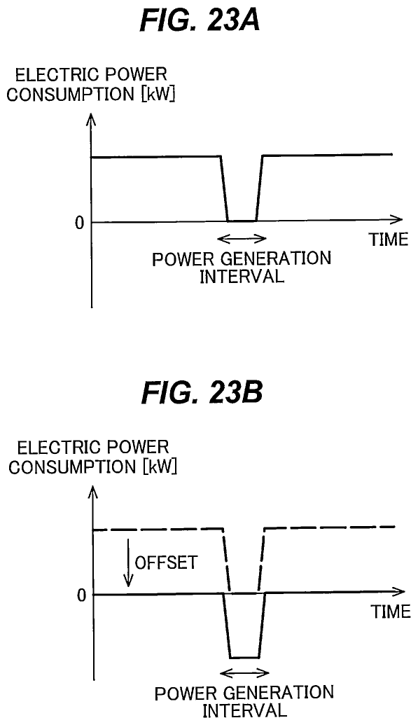

The offset subtraction unit 716 subtracts the offset value from the device electric power consumption of the device 701 #p corresponding to the electric power generating device. Specifically, the offset subtraction unit 716 subtracts the offset value added by the offset adding unit 714h, from a value of the individual electric power consumption of the device 701 #p corresponding to the electric power generating device, in the electric power consumption matrix provided from the analysis unit 114c. Consequently, the amount of electric power generated by the device 701 #p, which corresponds to the electric power generating device, is calculated as a negative electric power consumption. The following description will be given with reference to FIG. 23.

As described above, regarding the operating state of the device 701 #p corresponding to the electric power generating device, the coefficient matrix editing unit 714g edits the power generation interval in which the device is in the operating state of generating electric power to “0”, whereas it edits the non-power generation interval in which the device is in the non-operating state of not generating electric power to “1”. Then, the offset adding unit 714h adds the offset value to the total electric power consumption in the period n.

This corresponds to the assumption that there is a virtual device among the plurality of device 701 that consumes electric power corresponding to the offset value in the non-power generation interval and does not consume any electric power in the power generation interval, as illustrated in FIG. 23A.

Then, by subtracting the offset value from the individual electric power consumption of this virtual device in the period n, as illustrated in FIG. 23B, the individual electric power consumption of the device 701 #p is calculated as a negative electric power consumption; the device 701 #p corresponds to the electric power generating device that stops operating in the non-power generation interval and operates to generate electric power in the power generation interval.

As described above, the seventh embodiment can estimate an electric power consumption and an amount of electric power generated in each device 701 even when the plurality of devices 701 to be analyzed include the device 701 #p that corresponds to the electric power generating device.

The offset subtraction unit 716 described above can also be configured by the memory 10 and the processor 11 such as a CPU that executes a program stored in the memory 10, as illustrated in FIG. 6A, for example.

Alternatively, the offset subtraction unit 716 can also be configured by the processing circuit 12 such as a single circuit, a composite circuit, a programmed processor, a parallel programmed processor, an ASIC or an FPGA, as illustrated in FIG. 6B, for example.

### Eighth Embodiment

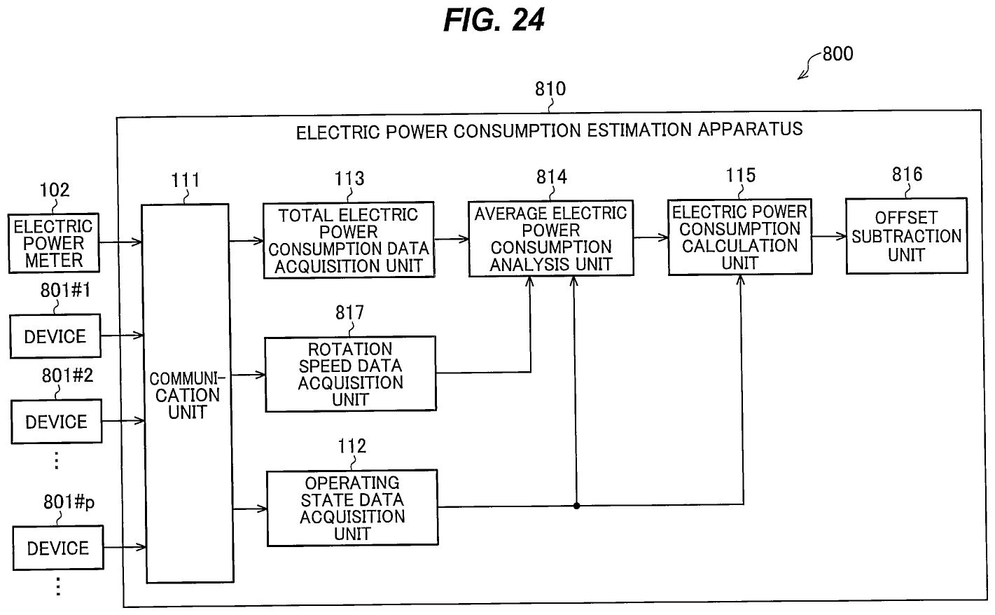

FIG. 24 is a block diagram schematically illustrating a configuration of an electric power consumption estimation system 800 including an electric power consumption estimation apparatus 810 according to an eighth embodiment.

The electric power consumption estimation system 800 includes a plurality of devices 801 #1, 801 #2, . . . , the electric power meter 102, and the electric power consumption estimation apparatus 810.

The electric power meter 102 of the electric power consumption estimation system 800 in the eighth embodiment is the same as the electric power meter 102 of the electric power consumption estimation system 100 in the first embodiment.

The devices 801 #1, 801 #2, . . . are those in which an electric power consumption is managed, such as home appliance devices in homes and FA devices in factories.

In the eighth embodiment, it is assumed that the plurality of devices 801 #1, 801 #2, . . . include a device 801 #p corresponding to a motor having a power supply regeneration function, in other words, an electric power generation function. The device 801 #p corresponding to the motor has, for example, the power supply regeneration function that generates electric power during deceleration.

In addition, when there is no need to particularly distinguish between the plurality of devices 801 #1, 801 #2, . . . , 801 #p, . . . , they are referred to as a device 801.

The device 801 transmits operating state data indicative of whether or not it is in an operating state to the electric power consumption estimation apparatus 810. The operating state data only needs to be data indicative of whether or not the device is in the operating state. For example, when the device 801 has a plurality of modes with different electric power consumptions, such as a normal mode and a power-saving mode in which an electric power consumption is smaller than that in the normal mode, the device 801 transmits data indicative of whether or not it is in the operating state for each mode to the electric power consumption estimation apparatus 810 as the operating state data.

Here, the device 801 #p corresponding to the motor consumes electric power in a constant speed state and an acceleration state. The device 801 #p generates electric power in a deceleration state. The device 801 #p is brought into the non-operating state and does not consume any electric power in a stop state. Thus, the device 801 #p corresponding to the motor exhibits a negative electric power consumption in the deceleration state in terms of electric power consumption.

In order to enable the detection of the operation state described above, the device 801 #p, which corresponds to the motor, also transmits rotation speed data indicative of the rotation speed of the motor to the electric power consumption estimation apparatus 810.

The electric power consumption estimation apparatus 810 can correlate the operating state data with the rotation speed data based on the information from a transmission source or the like.

Also in the eighth embodiment, the electric power consumption can be estimated when the device 801 #p having the electric power generation function is included in the devices 801.

The electric power consumption estimation apparatus 810 estimates a device electric power consumption, which is the electric power consumption of each of the plurality of devices 801, from the total electric power consumption indicated by the total electric power consumption data provided from the electric power meter 102.

The electric power consumption estimation apparatus 810 includes the communication unit 111, the operating state data acquisition unit 112, the total electric power consumption data acquisition unit 113, an average electric power consumption analysis unit 814, the electric power consumption calculation unit 115, an offset subtraction unit 816, and a rotation speed data acquisition unit 817.

The communication unit 111, the operating state data acquisition unit 112, the total electric power consumption data acquisition unit 113, and the electric power consumption calculation unit 115 of the electric power consumption estimation apparatus 810 in the eighth embodiment are the same as the communication unit 111, the operating state data acquisition unit 112, the total electric power consumption data acquisition unit 113, and the electric power consumption calculation unit 115 of the electric power consumption estimation apparatus 110 in the first embodiment, respectively.

It is noted that the electric power consumption calculation unit 115 provides the generated device electric power consumption time series data to the offset subtraction unit 816.

The rotation speed data acquisition unit 817 acquires the rotation speed data from the device 801 #p via the communication unit 111. The acquired rotation speed data is provided to the average electric power consumption analysis unit 814.

As in the first embodiment, the average electric power consumption analysis unit 814 estimates the individual electric power consumption, which is an average of the electric power consumption of each of the plurality of devices 801, from the total electric power consumption of the plurality of devices 801 and whether or not each of the plurality of devices 801 is in the operating state. However, in the eighth embodiment, since the devices 801 include a device 801 #p corresponding to a motor that generates electric power which becomes a negative electric power consumption, the average electric power consumption analysis unit 814 adds an offset value to the total electric power consumption so as to prevent the amount of electric power generated by the device 801 #p corresponding to the motor from becoming negative.

Then, the average electric power consumption analysis unit 814 estimates the operation state of the device 801 #p corresponding to the motor from its rotation speed, estimates the virtual mode of the device 801 #p corresponding to the motor from the estimated operation state, and identifies the operating state thereof in the virtual mode. The average electric power consumption analysis unit 814 then estimates the individual electric power consumption of each of the plurality of devices 801.

In the eighth embodiment, the average electric power consumption analysis unit 814 adds a predetermined offset value to the total electric power consumption. The offset value here is desirably greater than or equal to the amount of electric power generated by the device 801 #p corresponding to the motor in the predetermined period. The average electric power consumption analysis unit 814 then identifies a plurality of operation states of the device 801 #p corresponding to the motor according to the rotation speed of the device 801 #p corresponding to the motor and the magnitude of a change in the rotation speed of the device 801 #p corresponding to the motor. Further, the average electric power consumption analysis unit 814 assigns at least one of the plurality of virtual modes to each of those plurality of operation states such that the added electric power consumption, which is the electric power consumption of the device 801 #p corresponding to the motor with the offset value added, is consumed. Then, in the coefficient matrix, the average electric power consumption analysis unit 814 uses a value indicative of whether or not the device 801 #p corresponding to the motor is in the operating state in each of the plurality of virtual modes as a component.

The details thereof will be described below.

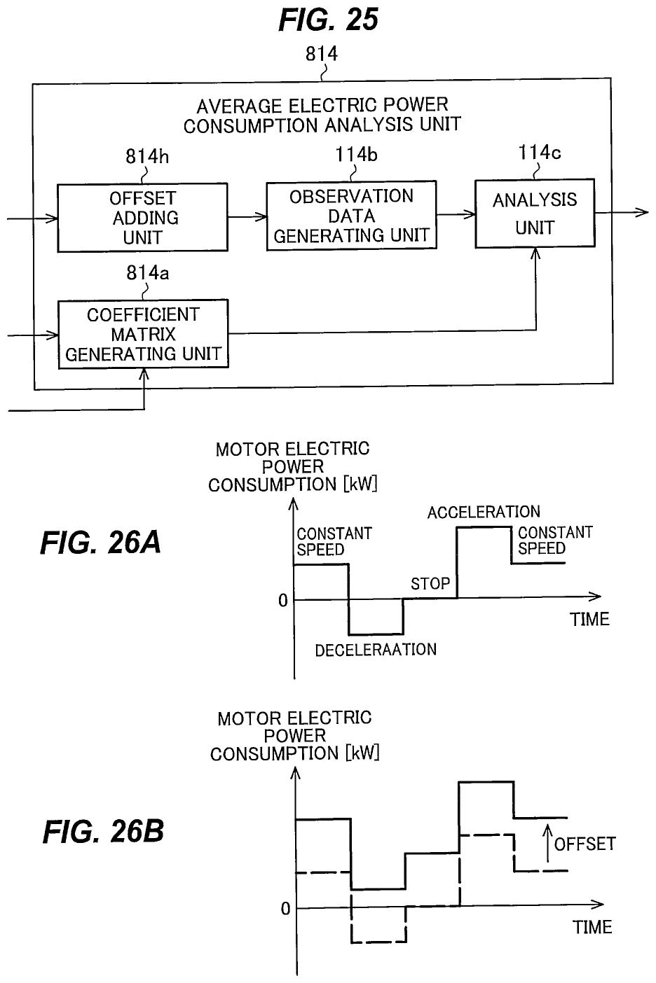

FIG. 25 is a block diagram schematically illustrating a configuration of the average electric power consumption analysis unit 814.

The average electric power consumption analysis unit 814 includes a coefficient matrix generating unit 814a, the observation data generating unit 114b, the analysis unit 114c, and an offset adding unit 814h.

The observation data generating unit 114b and the analysis unit 114c of the average electric power consumption analysis unit 814 in the eighth embodiment are the same as the observation data generating unit 114b and the analysis unit 114c of the average electric power consumption analysis unit 114 in the first embodiment.

The observation data generating unit 114b uses the added total electric power consumption data indicative of the total electric power consumption to which an offset is added by the offset adding unit 814h to generate an observation matrix indicative of the total electric power consumption to which the offset value is added for each period n.

The analysis unit 114c calculates an electric power consumption matrix from the coefficient matrix provided from the coefficient matrix generating unit 814a and the observation matrix. The analysis unit 114c then provides the calculated electric power consumption matrix to the offset subtraction unit 816.

The offset adding unit 814h adds an offset value to the total electric power consumption indicated by the total electric power consumption data provided from the total electric power consumption data acquisition unit 113; the offset value is greater than or equal to the negative electric power consumption, which is the amount of electric power generated by the device 801 #p corresponding to the motor in the period n. Here, the offset value is assumed to be predetermined based on the amount of electric power generated by the device 801 #p corresponding to the motor in the period n.

For example, as illustrated in FIG. 26A, the device 801 #p corresponding to the motor is assumed to be in the following operation states: the constant speed state in which it rotates at a constant rotation speed; the deceleration state in which it decreases its rotation speed; the stop state in which it does not rotate; and the acceleration state in which it increases its rotation speed. The constant speed state, the deceleration state, and the acceleration state correspond to the operating states, whereas the stop state corresponds to the non-operating state. The device 801 #p corresponding to the motor then generates electric power in the deceleration state. Such a device 801 #p exhibits a negative electric power consumption in the deceleration state where it generates electric power. However, as illustrated in FIG. 26B, by adding the offset value, its electric power consumption becomes non-negative. Consequently, the total electric power consumption also becomes non-negative.

The offset adding unit 814h then provides the added total electric power consumption data indicative of the added total electric power consumption, which is the total electric power consumption with the offset value added, to the observation data generating unit 114b.

The coefficient matrix generating unit 814a generates a coefficient matrix indicative of whether or not the device 801 is in the operating state in the specific period n, for each device 801 or for each mode when the device 801 has a plurality of modes, in the interval N.

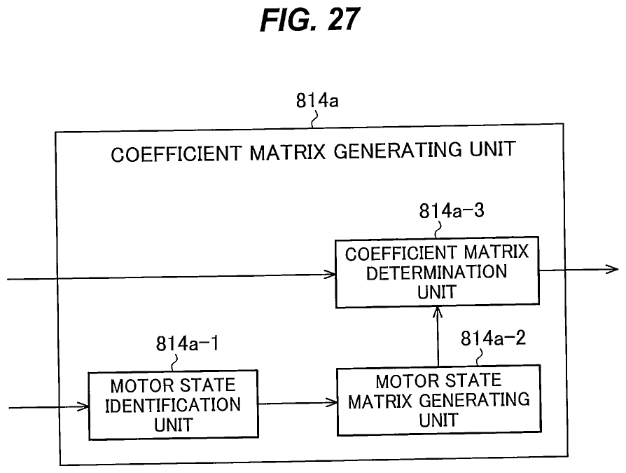

FIG. 27 is a block diagram schematically illustrating a configuration of the coefficient matrix generating unit 814a.

The coefficient matrix generating unit 814a includes a motor state identification unit 814a-1, a motor state matrix generating unit 814a-2, and a coefficient matrix determination unit 814a-3.

The motor state identification unit 814a-1 classifies the operation state of the device 801 #p corresponding to the motor into the constant speed state, the acceleration state, the deceleration state, or the stop state according to the rotation speed indicated by the rotation speed data provided from the rotation speed data acquisition unit 817 and the magnitude of a change thereof.

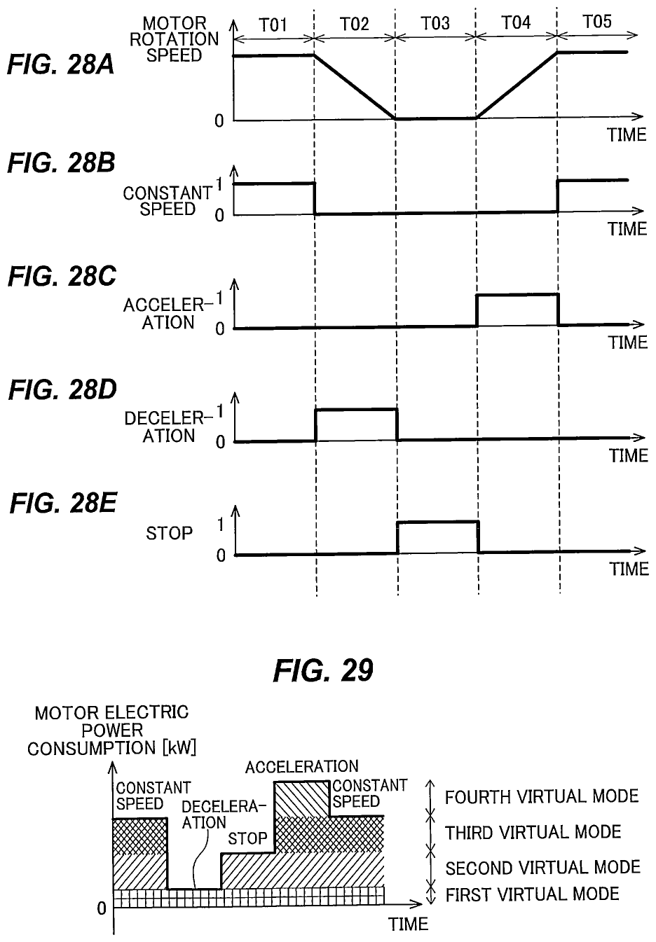

FIGS. 28A to 28E are schematic diagrams for explaining processing of classifying the operation state based on the rotation speed.

When the rotation speed of the device 801 #p corresponding to the motor is constant at a value greater than 0 as illustrated in intervals T01 and T05 of FIG. 28A, the motor state identification unit 814a-1 determines that the motor is in the constant speed state as illustrated in FIG. 28B.

When the rotation speed of the device 801 #p corresponding to the motor increases beyond a certain threshold value as illustrated in an interval T04 of FIG. 28A, the motor state identification unit 814a-1 determines that the motor is in the acceleration state as illustrated in FIG. 28C.

When the rotation speed of the device 801 #p corresponding to the motor decreases beyond a certain threshold value as illustrated in an interval T02 of FIG. 28A, the motor state identification unit 814a-1 determines that the motor is in the deceleration state as illustrated in FIG. 28D.

When the rotation speed of the device 801 #p corresponding to the motor is constant at zero as illustrated in an interval T03 of FIG. 28A, the motor state identification unit 814a-1 determines that the motor is in the stop state as illustrated in FIG. 28E. Returning to FIG. 27, the motor state matrix generating unit 814a-2 generates a motor state matrix that indicates whether or not the device 801 #p corresponding to the motor is in the operation state at a specific period n in the interval N.

For example, the motor state matrix generating unit 814a-2 can generate a matrix for each of the operation states identified by the motor state identification unit 814a-1, i.e., the constant speed state, the acceleration state, the deceleration state, and the stop state, by assigning “1” when the motor is in that operation state and “0” when it is not in that operation state, in the period n. The generated motor state matrix is provided to the coefficient matrix determination unit 814a-3.

The coefficient matrix determination unit 814a-3 specifies the operating state of the virtual mode of the device 801 #p, which corresponds to the motor, from the motor state matrix provided from the motor state matrix generating unit 814a-2.

For example, as illustrated in FIG. 29, the electric power consumption, to which the offset value is added, of the device 801 #p corresponding to the motor can be represented by a combination of first to fourth virtual modes. The first virtual mode is a virtual mode that consumes electric power equivalent to the electric power consumption in the deceleration state where the electric power consumption is the lowest. The second virtual mode is a virtual mode that consumes electric power obtained by subtracting the electric power consumption in the deceleration state from the electric power consumption in the stop state. The third virtual mode is a virtual mode that consumes electric power obtained by subtracting the electric power consumption in the stop state from the electric power consumption in the acceleration state. The fourth virtual mode is a virtual mode that consumes electric power obtained by subtracting the electric power consumption in the constant speed state from the electric power consumption in the acceleration state.

Specifically, the constant speed state can be determined to consume electric power when the first, second, and third virtual modes are in the operating state.

The deceleration state can be determined to consume electric power when the first virtual mode is in the operating state.

The stop state can be determined to consume electric power when the first and second virtual modes are in the operating state.

The acceleration state can be determined to consume electric power when the first, second, third, and fourth virtual modes are in the operating state.

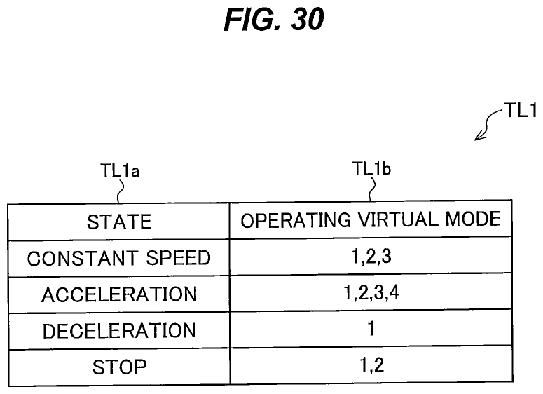

The above relationship between the operation state and the virtual mode can be represented as an operation mode conversion table TL1 illustrated in FIG. 30.

The operation mode conversion table TL1 includes a state column TL1a and a virtual mode column TL1b. The operation state stored in the state column TL1a consumes electric power when the corresponding virtual mode stored in the virtual mode column TL1b is brought into the operating state. The operation mode conversion table TL1 only needs to be stored in a storage unit, not shown, of the electric power consumption estimation apparatus 810.

The coefficient matrix determination unit 814a-3 generates a coefficient matrix indicative of whether or not the device 801 is in the operating state in the specific period n, for each device 801 or for each mode when the device 801 has a plurality of modes, in the interval N, as in the coefficient matrix generating unit 114a of the first embodiment.

However, regarding the device 801 #p corresponding to the motor, the coefficient matrix determination unit 814a-3 specifies the operating state of the virtual mode of the device 801 #p, which corresponds to the motor, from the motor state matrix provided from the motor state matrix generating unit 814a-2, and then generates a coefficient matrix to indicate the operating state for each specified virtual mode.

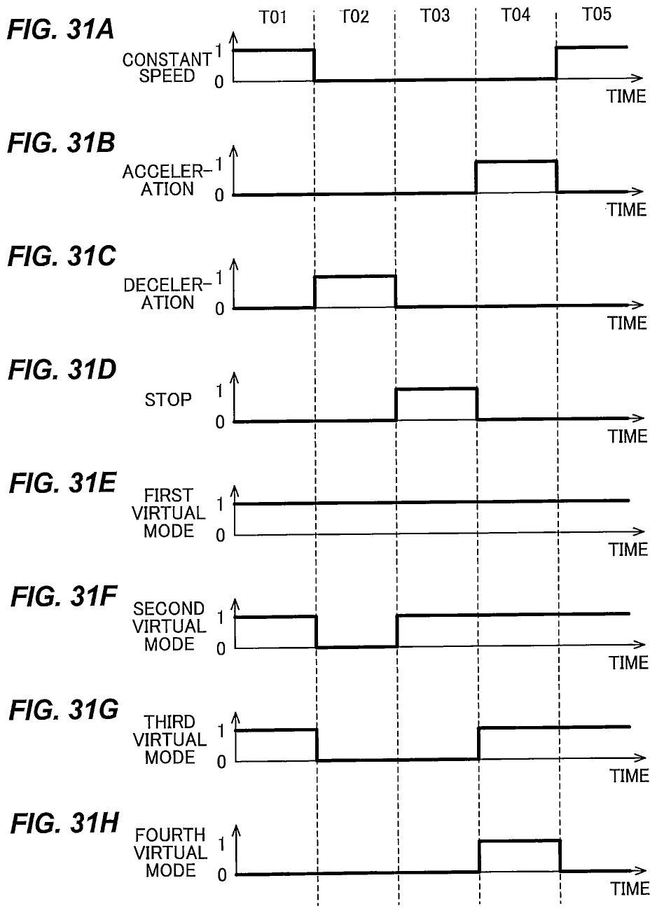

For example, the coefficient matrix determination unit 814a-3 refers to the operation mode conversion table TL1 with regard to the period n included in the intervals T01 and T05 where the constant speed state is set to “1” in the motor state matrix as illustrated in FIG. 31A. It then sets the first, second and third virtual modes to “1”, in other words, the operating state, as illustrated in FIGS. 31E, 31F and 31G.

Further, the coefficient matrix determination unit 814a-3 refers to the operation mode conversion table TL1 with regard to the period n included in the interval T04 where the acceleration state is set to “1” in the motor state matrix as illustrated in FIG. 31B. It then sets the first, second, third and fourth virtual modes to “1”, as illustrated in FIGS. 31E, 31F, 31G and 31H,

Furthermore, the coefficient matrix determination unit 814a-3 refers to the operation mode conversion table TL1 with regard to the period n included in the interval T02 where the deceleration state is “1” in the motor state matrix as illustrated in FIG. 31C. It then sets the first virtual mode to “1”, as illustrated in FIG. 31E.

In addition, the coefficient matrix determination unit 814a-3 refers to the operation mode conversion table TL1 with regard to the period n included in the interval T03 where the stop state is set to “1” in the motor state matrix as illustrated in FIG. 31D. It then sets the first and second virtual modes to “1”, as illustrated in FIGS. 31E and 31F.

Then, the coefficient matrix determination unit 814a-3 provides the generated coefficient matrix to the analysis unit 114c.

Returning to FIG. 24, the offset subtraction unit 816 subtracts the offset value added by the offset adding unit 814h from the individual electric power consumption of the device 801 #p corresponding to the motor in the electric power consumption matrix provided from the analysis unit 114c. Thus, the amount of electric power generated by the device 801 #p corresponding to the motor is calculated as a negative electric power consumption.

As described above, the eighth embodiment can estimate the electric power consumption and amount of electric power generated by each device 801 even when the plurality of devices 801 to be analyzed include a device, such as a motor, that generates and consumes electric power.

The offset subtraction unit 816 described above can also be configured by the memory 10 and the processor 11, such as a CPU, which executes a program stored in the memory 10, as illustrated in FIG. 6A, for example.

Alternatively, the offset subtraction unit 816 can also be configured by the processing circuit 12 such as a single circuit, a composite circuit, a programmed processor, a parallel programmed processor, an ASIC or an FPGA, as illustrated in FIG. 6B, for example.

In the seventh and eighth embodiments described above, the device electric power consumption is calculated using the period n. However, the seventh and eighth embodiments are not limited to such an example. Also, in the seventh and eighth embodiments, for example, the device electric power consumption may be calculated using the time frame T, as described in the second embodiment.

For example, when the time frame T is used in the seventh embodiment, the average electric power consumption analysis unit 714 inverts the value of whether or not the device 701 #p corresponding to the power generating device is in the operating state in the coefficient matrix from the operating state data, and then averages the inverted data over the time frame T.

When the time frame T is used in the eighth embodiment, the average electric power consumption analysis unit 814 may generate a coefficient matrix that has as its components, values obtained by averaging, over the time frame T, values indicative of whether or not the device 801 #p corresponding to the motor is in the operating state for each period, in each of the plurality of virtual modes.

The techniques described in the third to sixth embodiments can also be applied to the seventh and eighth embodiments described above.

What is claimed is:

1. An electric power consumption estimation apparatus, comprising:
processing circuitry
to acquire total electric power consumption data indicative of a total electric power consumption from an electric power meter, the electric power meter being configured to measure a sum of electric power consumptions of a plurality of devices as the total electric power consumption for each predetermined period;
to acquire operating state data indicative of whether or not each of the plurality of devices is in an operating state, from each of the devices;
to estimate an average electric power consumption of each of the plurality of devices from the total electric power consumption and whether or not each of the devices is in the operating state; and
to calculate a device electric power consumption by using the average electric power consumption, the device electric power consumption being an electric power consumption of each of the plurality of devices for each period, wherein
the processing circuitry calculates an electric power consumption matrix by using an equation, the equation stating that a product of the electric power consumption matrix and a coefficient matrix results in an observation matrix, the electric power consumption matrix having the average electric power consumption of each of the plurality of devices as a component thereof, the coefficient matrix having, as components thereof, values indicative of the plurality of devices and of whether or not the devices are in the operating state corresponding to the period, the observation matrix having the total electric power consumption corresponding to the period as components thereof.

2. An electric power consumption estimation apparatus, comprising:
processing circuitry
to acquire total electric power consumption data indicative of a total electric power consumption from an electric power meter, the electric power meter being configured to measure a sum of electric power consumptions of a plurality of devices as the total electric power consumption for each predetermined period, the plurality of devices including an electric power generating device configured to generate electric power;
to acquire operating state data indicative of whether or not each of the plurality of devices is in an operating state, from each of the devices;
to estimate an average electric power consumption of each of the plurality of devices from the total electric power consumption and whether or not each of the devices is in the operating state; and
to calculate a device electric power consumption by using the average electric power consumption, the device electric power consumption being an electric power consumption of each of the plurality of devices for each period, wherein
the processing circuitry adds a predetermined offset value to the total electric power consumption, then estimates the average electric power consumption of each of the plurality of devices from the total electric power consumption to which the offset value is added and whether or not the devices are in the operating state, and subtracts the offset value from the device electric power consumption of the electric power generating device.

3. The electric power consumption estimation apparatus according to claim 2,
wherein the average electric power consumption estimation unit is configured to calculate an electric power consumption matrix by using an equation, the equation stating that a product of the electric power consumption matrix and a coefficient matrix results in an observation matrix, the electric power consumption matrix having the average electric power consumption of each of the plurality of devices as a component thereof, the coefficient matrix having as components thereof values indicative of the plurality of devices and of whether or not the devices are in the operating state corresponding to the period, the observation matrix having the total electric power consumption corresponding to the period as components thereof, and
wherein the processing circuitry inverts a value of whether or not the electric power generating device is in the operating state in the coefficient matrix from the operating state data.

4. The electric power consumption estimation apparatus according to claim 1,
wherein when one device included in the plurality of devices has a plurality of modes with different electric power consumptions, the operating state data indicates whether or not the one device is in the operating state in each of the plurality of modes, and
wherein the coefficient matrix has, as a component, a value indicative of whether the one device is in the operating state in each of the plurality of modes when the one device has the plurality of modes.

5. The electric power consumption estimation apparatus according to claim 1,
wherein the plurality of devices includes a motor that has a power supply regeneration function of generating electric power during deceleration, and
wherein the processing circuitry adds a predetermined offset value to the total electric power consumption, identifies a plurality of operation states of the motor according to a rotation speed of the motor and a magnitude of a change in the rotation speed of the motor, assigns at least one of a plurality of virtual modes to each of the plurality of operation states such that an added electric power consumption, which is an electric power consumption of the motor with the offset value added, is consumed, and uses a value indicative of whether or not the motor is in the operating state in each of the plurality of virtual modes as a component in the coefficient matrix.

6. The electric power consumption estimation apparatus according to claim 5,
wherein when one device included in the plurality of devices has a plurality of modes with different electric power consumptions, the operating state data indicates whether or not the one device is in the operating state in each of the plurality of modes, and
wherein the coefficient matrix has, as a component, a value indicative of whether the one device is in the operating state in each of the plurality of modes when the one device has the plurality of modes.

7. An electric power consumption estimation apparatus, comprising:
processing circuitry
to acquire total electric power consumption data indicative of a total electric power consumption from an electric power meter, the electric power meter being configured to measure a sum of electric power consumptions of a plurality of devices as the total electric power consumption for each predetermined period;
to acquire operating state data indicative of whether or not each of the plurality of devices is in an operating state, from each of the devices;
to estimate an average electric power consumption of each of the plurality of devices from the total electric power consumption and whether or not each of the devices is in the operating state; and
to calculate a device electric power consumption by using the average electric power consumption, the device electric power consumption being an electric power consumption of each of the plurality of devices for each period, wherein
the processing circuitry calculates an electric power consumption matrix by using an equation, the equation stating that a product of the electric power consumption matrix and a coefficient matrix results in an observation matrix, the electric power consumption matrix having the average electric power consumption of each of the plurality of devices as a component thereof, the coefficient matrix having, as components thereof, values obtained by averaging, over a time frame longer than the period, values indicative of the plurality of devices and of whether or not the devices are in the operating state corresponding to the period, the observation matrix having an average total electric power consumption obtained by averaging the total electric power consumptions in the periods included in the time frame as components thereof.

8. The electric power consumption estimation apparatus according to claim 2,
wherein the processing circuitry calculates an electric power consumption matrix by using an equation, the equation stating that a product of the electric power consumption matrix and a coefficient matrix results in an observation matrix, the electric power consumption matrix having an average electric power consumption of each of the plurality of devices as a component thereof, the coefficient matrix having, as components thereof, values obtained by averaging, over a time frame longer than the period, values indicative of the plurality of devices and of whether or not the devices are in the operating state corresponding to the period, the observation matrix having an average total electric power consumption obtained by averaging the total electric power consumptions in the periods included in the time frame as components thereof, and
wherein the processing circuitry inverts a value of whether or not the electric power generating device is in the operating state in the coefficient matrix from the operating state data.

9. The electric power consumption estimation apparatus according to claim 7, wherein the plurality of devices includes a motor that has a power supply regeneration function of generating electric power during deceleration, and
wherein the processing circuitry adds a predetermined offset value to the total electric power consumption, identifies a plurality of operation states of the motor according to a rotation speed of the motor and a magnitude of a change in the rotation speed of the motor, assigns at least one of a plurality of virtual modes to each of the plurality of operation states such that an added electric power consumption, which is an electric power consumption of the motor with the offset value added, is consumed, and uses a value obtained by averaging values indicative of whether or not the motor is in the operating state for each period in each of the plurality of virtual modes over the time frame, as a component in the coefficient matrix.

10. An electric power consumption estimation apparatus, comprising:
processing circuitry
to acquire total electric power consumption data indicative of a total electric power consumption from an electric power meter, the electric power meter being configured to measure a sum of electric power consumptions of a plurality of devices as the total electric power consumption for each predetermined period;
to acquire operating state data indicative of whether or not each of the plurality of devices is in an operating state, from each of the devices;
to estimate an average electric power consumption of each of the plurality of devices from the total electric power consumption and whether or not each of the devices is in the operating state; and
to calculate a device electric power consumption by using the average electric power consumption, the device electric power consumption being an electric power consumption of each of the plurality of devices for each period, wherein
the processing circuitry calculates an electric power consumption matrix by using an equation and the device electric power consumption by multiplying the average electric power consumption by a value indicative of whether or not the device is in the operating state and then adding, to said obtained value, a value which becomes larger as the variance increases, the equation stating that a product of the electric power consumption matrix and a coefficient matrix results in an observation matrix, the electric power consumption matrix having the average electric power consumption of each of the plurality of devices and a variance of the electric power consumption of each of the plurality of devices as components thereof, the coefficient matrix having, as components thereof, values obtained by averaging, over a time frame longer than the period, values indicative of the plurality of devices and of whether or not the devices are in the operating state corresponding to the period, the observation matrix having, as components thereof, an average total electric power consumption obtained by averaging the total electric power consumptions in the periods included in the time frame, as well as a sum of a square of the average total electric power consumption and a sample variance of the total electric power consumption in the time frame.

11. The electric power consumption estimation apparatus according to claim 7,
wherein when one device included in the plurality of devices has a plurality of modes with different electric power consumptions, the operating state data indicates whether or not the one device is in the operating state in each of the plurality of modes, and
wherein the coefficient matrix has, as a component, a value obtained by averaging, over the time frame, values indicative of whether the one device is in the operating state in each of the plurality of modes when the one device has the plurality of modes.

12. The electric power consumption estimation apparatus according to claim 11,
wherein when an operating state of each of the plurality of devices or an operating state indicated by one mode included in the plurality of modes continues for a predetermined threshold value or more, the processing circuitry generates a coefficient matrix by using an operating state during an interval up to the predetermined threshold value as one mode and an operating state during an interval following the predetermined threshold value as another mode.

13. The electric power consumption estimation apparatus according to claim 1, wherein when an unknown device that does not transmit the operating state data is included in the plurality of devices, the processing circuitry includes, in the coefficient matrix, a component that shows a value indicative of whether or not the unknown device is in a predetermined operating state, as a value indicative of whether or not the unknown device is in the operating state.

14. The electric power consumption estimation apparatus according claim 1, wherein the processing circuitry calculates the electric power consumption matrix by multiplying the equation by an inverse of the coefficient matrix.

15. The electric power consumption estimation apparatus according to claim 1, wherein the processing circuitry calculates the electric power consumption matrix by performing matrix factorization on the observation matrix by using the coefficient matrix as a constraint condition.

16. The electric power consumption estimation apparatus according to claim 1, wherein the processing circuitry sequentially calculates the electric power consumption matrices and stops calculating a new electric power consumption matrix when the electric power consumption matrices satisfy a predetermined convergence condition.

17. A non-transitory computer-readable storage medium storing a program causing a computer to execute processing comprising:
acquiring total electric power consumption data indicative of a total electric power consumption from an electric power meter, the electric power meter being configured to measure a sum of electric power consumptions of a plurality of devices as the total electric power consumption for each predetermined period;
acquiring operating state data indicative of whether or not each of the plurality of devices is in an operating state, from each of the devices;
estimating an average electric power consumption of each of the plurality of devices from the total electric power consumption and whether or not each of the devices is in the operating state;
calculating a device electric power consumption by using the average electric power consumption, the device electric power consumption being an electric power consumption of each of the plurality of devices for each period; and
calculating an electric power consumption matrix by using an equation, the equation stating that a product of the electric power consumption matrix and a coefficient matrix results in an observation matrix, the electric power consumption matrix having the average electric power consumption of each of the plurality of devices as a component thereof, the coefficient matrix having, as components thereof, values indicative of the plurality of devices and of whether or not the devices are in the operating state corresponding to the period, the observation matrix having the total electric power consumption corresponding to the period as components thereof.

18. A non-transitory computer-readable storage medium storing a program causing a computer to execute processing comprising:
acquiring total electric power consumption data indicative of a total electric power consumption from an electric power meter, the electric power meter being configured to measure a sum of electric power consumptions of a plurality of devices as the total electric power consumption for each predetermined period, the plurality of devices including an electric power generating device configured to generate electric power;
acquiring operating state data indicative of whether or not each of the plurality of devices is in an operating state, from each of the devices;
estimating an average electric power consumption of each of the plurality of devices from the total electric power consumption and whether or not each of the devices is in the operating state;
calculating a device electric power consumption by using the average electric power consumption, the device electric power consumption being an electric power consumption of each of the plurality of devices for each period;
adding a predetermined offset value to the total electric power consumption;
estimating the average electric power consumption of each of the plurality of devices from the total electric power consumption to which the offset value is added and whether or not the devices are in the operating state; and
subtracting the offset value from the device electric power consumption of the electric power generating device.

19. A non-transitory computer-readable storage medium storing a program causing a computer to execute processing comprising:
acquiring total electric power consumption data indicative of a total electric power consumption from an electric power meter, the electric power meter being configured to measure a sum of electric power consumptions of a plurality of devices as the total electric power consumption for each predetermined period;
acquiring operating state data indicative of whether or not each of the plurality of devices is in an operating state, from each of the devices;
estimating an average electric power consumption of each of the plurality of devices from the total electric power consumption and whether or not each of the devices is in the operating state;
calculating a device electric power consumption by using the average electric power consumption, the device electric power consumption being an electric power consumption of each of the plurality of devices for each period; and
calculating an electric power consumption matrix by using an equation, the equation stating that a product of the electric power consumption matrix and a coefficient matrix results in an observation matrix, the electric power consumption matrix having the average electric power consumption of each of the plurality of devices as a component thereof, the coefficient matrix having, as components thereof, values obtained by averaging, over a time frame longer than the period, values indicative of the plurality of devices and of whether or not the devices are in the operating state corresponding to the period, the observation matrix having an average total electric power consumption obtained by averaging the total electric power consumptions in the periods included in the time frame as components thereof.

20. A non-transitory computer-readable storage medium storing a program causing a computer to function as to execute processing comprising:
acquiring total electric power consumption data indicative of a total electric power consumption from an electric power meter, the electric power meter being configured to measure a sum of electric power consumptions of a plurality of devices as the total electric power consumption for each predetermined period;
acquiring operating state data indicative of whether or not each of the plurality of devices is in an operating state, from each of the devices;
estimating an average electric power consumption of each of the plurality of devices from the total electric power consumption and whether or not each of the devices is in the operating state;
calculating a device electric power consumption by using the average electric power consumption, the device electric power consumption being an electric power consumption of each of the plurality of devices for each period; and
calculating an electric power consumption matrix by using an equation and the device electric power consumption by multiplying the average electric power consumption by a value indicative of whether or not the device is in the operating state and then adding, to said obtained value, a value which becomes larger as the variance increases, the equation stating that a product of the electric power consumption matrix and a coefficient matrix results in an observation matrix, the electric power consumption matrix having the average electric power consumption of each of the plurality of devices and a variance of the electric power consumption of each of the plurality of devices as components thereof, the coefficient matrix having, as components thereof, values obtained by averaging, over a time frame longer than the period, values indicative of the plurality of devices and of whether or not the devices are in the operating state corresponding to the period, the observation matrix having, as components thereof, an average total electric power consumption obtained by averaging the total electric power consumptions in the periods included in the time frame, as well as a sum of a square of the average total electric power consumption and a sample variance of the total electric power consumption in the time frame.

21. An electric power consumption estimation method, comprising:
acquiring total electric power consumption data indicative of a total electric power consumption from an electric power meter, the electric power meter being configured to measure a sum of electric power consumptions of a plurality of devices as the total electric power consumption for each predetermined period;
acquiring operating state data indicative of whether or not each of the plurality of devices is in an operating state, from each of the devices;
estimating an average electric power consumption of each of the plurality of devices from the total electric power consumption and whether or not each of the devices is in the operating state;
calculating a device electric power consumption by using the average electric power consumption, the device electric power consumption being an electric power consumption of each of the plurality of devices for each period; and
calculating an electric power consumption matrix by using an equation, the equation stating that a product of the electric power consumption matrix and a coefficient matrix results in an observation matrix, the electric power consumption matrix having the average electric power consumption of each of the plurality of devices as a component thereof, the coefficient matrix having, as components thereof, values indicative of the plurality of devices and of whether or not the devices are in the operating state corresponding to the period, the observation matrix having the total electric power consumption corresponding to the period as components thereof.

22. An electric power consumption estimation method, comprising:
acquiring total electric power consumption data indicative of a total electric power consumption from an electric power meter, the electric power meter being configured to measure a sum of electric power consumptions of a plurality of devices as the total electric power consumption for each predetermined period, the plurality of devices including an electric power generating device configured to generate electric power;
acquiring operating state data indicative of whether or not each of the plurality of devices is in an operating state, from each of the devices;
estimating an average electric power consumption of each of the plurality of devices from the total electric power consumption and whether or not each of the devices is in the operating state;
calculating a device electric power consumption by using the average electric power consumption, the device electric power consumption being an electric power consumption of each of the plurality of devices for each period;
adding a predetermined offset value to the total electric power consumption;
estimating the average electric power consumption of each of the plurality of devices from the total electric power consumption to which the offset value is added and whether or not the devices are in the operating state; and
subtracting the offset value from the device electric power consumption of the electric power generating device.

23. An electric power consumption estimation method, comprising:
acquiring total electric power consumption data indicative of a total electric power consumption from an electric power meter, the electric power meter being configured to measure a sum of electric power consumptions of a plurality of devices as the total electric power consumption for each predetermined period;
acquiring operating state data indicative of whether or not each of the plurality of devices is in an operating state, from each of the devices;
estimating an average electric power consumption of each of the plurality of devices from the total electric power consumption and whether or not each of the devices is in the operating state;
calculating a device electric power consumption by using the average electric power consumption, the device electric power consumption being an electric power consumption of each of the plurality of devices for each period; and
calculating an electric power consumption matrix by using an equation, the equation stating that a product of the electric power consumption matrix and a coefficient matrix results in an observation matrix, the electric power consumption matrix having the average electric power consumption of each of the plurality of devices as a component thereof, the coefficient matrix having, as components thereof, values obtained by averaging, over a time frame longer than the period, values indicative of the plurality of devices and of whether or not the devices are in the operating state corresponding to the period, the observation matrix having an average total electric power consumption obtained by averaging the total electric power consumptions in the periods included in the time frame as components thereof.

24. An electric power consumption estimation method, comprising:
acquiring total electric power consumption data indicative of a total electric power consumption from an electric power meter, the electric power meter being configured to measure a sum of electric power consumptions of a plurality of devices as the total electric power consumption for each predetermined period;
acquiring operating state data indicative of whether or not each of the plurality of devices is in an operating state, from each of the devices;
estimating an average electric power consumption of each of the plurality of devices from the total electric power consumption and whether or not each of the devices is in the operating state;
calculating a device electric power consumption by using the average electric power consumption, the device electric power consumption being an electric power consumption of each of the plurality of devices for each period; and
calculating an electric power consumption matrix by using an equation and the device electric power consumption by multiplying the average electric power consumption by a value indicative of whether or not the device is in the operating state and then adding, to said obtained value, a value which becomes larger as the variance increases, the equation stating that a product of the electric power consumption matrix and a coefficient matrix results in an observation matrix, the electric power consumption matrix having the average electric power consumption of each of the plurality of devices and a variance of the electric power consumption of each of the plurality of devices as thereof, components the coefficient matrix having, as components thereof, values obtained by averaging, over a time frame longer than the period, values indicative of the plurality of devices and of whether or not the devices are in the operating state corresponding to the period, the observation matrix having, as components thereof, an average total electric power consumption obtained by averaging the total electric power consumptions in the periods included in the time frame, as well as a sum of a square of the average total electric power consumption and a sample variance of the total electric power consumption in the time frame.
